(19) United States
(12) Patent Application Publication
(10) Pub. No.: US 2026/0047107 A1
(43) Pub. Date: Feb. 12, 2026

(54) MEMORY DEVICE

(71) Applicant: Kioxia Corporation, Tokyo (JP)

(72) Inventors: Tomoya Inden, Yokkaichi Mie (JP); Yoshihiro Kubota, Yokkaichi Mie (JP)

(73) Assignee: Kioxia Corporation, Tokyo (JP)

(21) Appl. No.: 19/057,459

(22) Filed: Feb. 19, 2025

(30) Foreign Application Priority Data
Aug. 7, 2024 (JP) 2024-131111

(51) Int. Cl. H10B 80/00; H01L 23/00; H01L 25/00; H01L 25/065; H01L 25/18; H10B 43/10; H10B 43/27

(52) U.S. Cl. CPC H10B 80/00; H01L 24/08; H01L 24/80; H01L 25/0657; H01L 25/18; H01L 25/50; H10B 43/10; H10B 43/27; H01L 2224/08145; H01L 2224/80895; H01L 2224/80896; H01L 2924/1431; H01L 2924/14511

(57) ABSTRACT

According to one embodiment, a memory device includes: a first substrate, a second substrate, and wiring layers arranged apart from each other in this order in a first direction, the wiring layers being arranged apart from each other in the first direction; a memory pillar extending in the first direction and having portions intersecting with respective wiring layers to function as memory cells; a conductive film provided on a surface of the second substrate alongside the wiring layers; a first contact extending in the first direction at a side of the wiring layers relative to the conductive film and in contact with the conductive film; and a second contact extending in the first direction to intersect with the second substrate at a side of the first substrate relative to the conductive film, and in contact with the conductive film.

### CROSS-REFERENCE TO RELATED APPLICATIONS

This application is based upon and claims the benefit of priority from Japanese Patent Application No. 2024-131111, filed Aug. 7, 2024, the entire contents of which are incorporated herein by reference.

### FIELD

Embodiments described herein relate generally to a memory device.

### BACKGROUND

A NAND flash memory is known as a memory device capable of storing data in a nonvolatile manner. Such a memory device has a three-dimensional memory structure adopted for high integration and large capacity.

### BRIEF DESCRIPTION OF THE DRAWINGS

FIG. 1 is a block diagram showing an example of a configuration of a memory system including a memory device according to a first embodiment.

FIG. 2 is a circuit diagram showing an example of a circuit configuration of a memory cell array included in the memory device according to the first embodiment.

FIG. 3 is a plan view showing an example of a planar layout of the memory cell array included in the memory device according to the first embodiment.

FIG. 4 is a plan view showing an example of region IV of FIG. 3 in the planar layout of the memory cell array included in the memory device according to the first embodiment.

FIG. 5 is a cross-sectional view taken along line V-V of FIG. 4 and showing an example of a cross-sectional structure of the memory cell array included in the memory device according to the first embodiment.

FIG. 6 is a cross-sectional view taken along line VI-VI of FIG. 5 and showing an example of a cross-sectional structure of a memory pillar included in the memory cell array according to the first embodiment.

FIG. 7 is a perspective view showing an outline of a bonding structure of the memory device according to the first embodiment.

FIG. 8 is a cross-sectional view showing an example of a cross-sectional structure of the memory device according to the first embodiment.

FIG. 9 is a cross-sectional view showing an example of a cross-sectional structure of a bonding pad included in the memory device according to the first embodiment.

FIG. 10 is a cross-sectional view showing an example of the cross-sectional structure of the memory device according to the first embodiment which is in the process of being manufactured.

FIG. 11 is a cross-sectional view showing an example of the cross-sectional structure of the memory device according to the first embodiment which is in the process of being manufactured.

FIG. 12 is a cross-sectional view showing an example of the cross-sectional structure of the memory device according to the first embodiment which is in the process of being manufactured.

FIG. 13 is a cross-sectional view showing an example of the cross-sectional structure of the memory device according to the first embodiment which is in the process of being manufactured.

FIG. 14 is a cross-sectional view showing an example of the cross-sectional structure of the memory device according to the first embodiment which is in the process of being manufactured.

FIG. 15 is a cross-sectional view showing an example of the cross-sectional structure of the memory device according to the first embodiment which is in the process of being manufactured.

FIG. 16 is a cross-sectional view showing an example of the cross-sectional structure of the memory device according to the first embodiment which is in the process of being manufactured.

FIG. 17 is a cross-sectional view showing an example of the cross-sectional structure of the memory device according to the first embodiment which is in the process of being manufactured.

FIG. 18 is a cross-sectional view showing an example of a cross-sectional structure of a memory device according to a first modification to the first embodiment.

FIG. 19 is a cross-sectional view showing an example of a cross-sectional structure of a memory device according to a second modification to the first embodiment.

FIG. 20 is a cross-sectional view showing an example of a cross-sectional structure of a memory device according to a third modification to the first embodiment.

FIG. 21 is a cross-sectional view showing an example of a cross-sectional structure of a memory device according to a fourth modification to the first embodiment.

FIG. 22 is a cross-sectional view showing an example of a cross-sectional structure of a memory device according to a second embodiment.

FIG. 23 is a cross-sectional view showing an example of the cross-sectional structure of the memory device according to the second embodiment which is in the process of being manufactured.

FIG. 24 is a cross-sectional view showing an example of the cross-sectional structure of the memory device according to the second embodiment which is in the process of being manufactured.

FIG. 25 is a cross-sectional view showing an example of the cross-sectional structure of the memory device according to the second embodiment which is in the process of being manufactured.

FIG. 26 is a cross-sectional view showing an example of the cross-sectional structure of the memory device according to the second embodiment which is in the process of being manufactured.

FIG. 27 is a cross-sectional view showing an example of the cross-sectional structure of the memory device according to the second embodiment which is in the process of being manufactured.

FIG. 28 is a cross-sectional view showing an example of the cross-sectional structure of the memory device according to the second embodiment which is in the process of being manufactured.

FIG. 29 is a cross-sectional view showing an example of a cross-sectional structure of a memory device according to a first modification to the second embodiment.

FIG. 30 is a cross-sectional view showing an example of a cross-sectional structure of a memory device according to a second modification to the second embodiment.

FIG. 31 is a cross-sectional view showing an example of a cross-sectional structure of a memory device according to a third modification to the second embodiment.

### DETAILED DESCRIPTION

According to one embodiment, a memory device includes: a first substrate, a second substrate, and a plurality of wiring layers arranged apart from each other in this order in a first direction, the wiring layers being arranged apart from each other in the first direction; a memory pillar extending in the first direction and having portions intersecting with respective wiring layers to function as memory cells; a conductive film provided on a surface of the second substrate alongside the wiring layers; a first contact extending in the first direction at a side of the wiring layers relative to the conductive film and being in contact with the conductive film; and a second contact extending in the first direction to intersect with the second substrate at a side of the first substrate relative to the conductive film, and being in contact with the conductive film.

Embodiments will be described below with reference to the drawings. The dimensions or ratios in the drawings are not necessarily the same as the actual ones.

In the following description, components having substantially the same or similar function and configuration are denoted by the same reference symbol. To distinguish the components more specifically, different letters or numerals may be added to the ends of the same reference symbols.

### 1. FIRST EMBODIMENT

### 1.1 Configuration

### 1.1.1 Configuration of Memory System

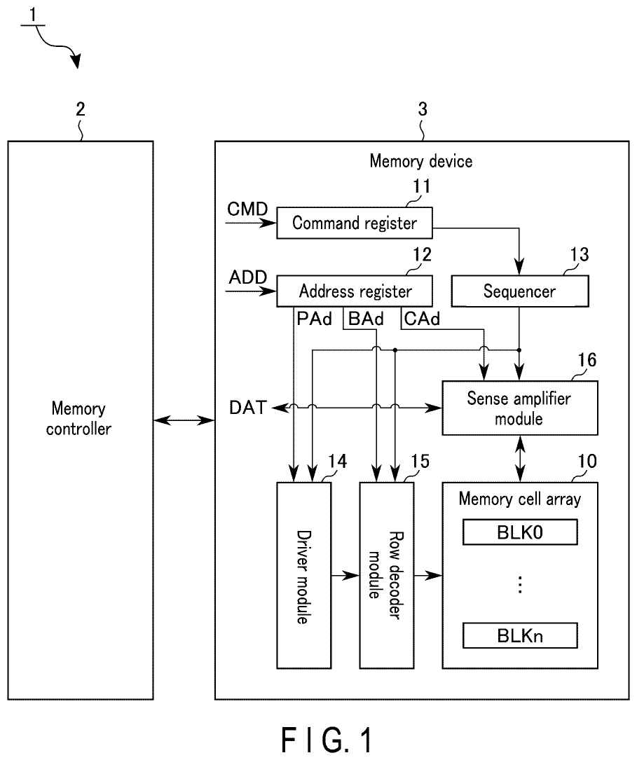

FIG. 1 is a block diagram showing an example of a configuration of a memory system including a memory device according to a first embodiment. The memory system 1 is a storage device configured to be coupled to an external host (not shown). The memory system 1 is, for example, a memory card such as an SD™ card, a universal flash storage (UFS), and a solid-state drive (SSD). The memory system 1 includes a memory controller 2 and a memory device 3.

The memory controller 2 is configured by an integrated circuit such as a system-on-a-chip (SoC). The memory controller 2 controls the memory device 3 upon request from the host. Specifically, for example, the memory controller 2 writes data to the memory device 3 upon request from the host. The memory controller 2 also reads data from the memory device 3 upon request from the host and then transmits it to the host.

The memory device 3 is a nonvolatile memory. The memory device 3 is, for example, a NAND flash memory. The memory device 3 stores data in a nonvolatile manner.

The memory controller 2 and the memory device 3 communicate with each other based on a single data rate (SDR) interface, a toggle double data rate (DDR) interface, an open NAND flash interface (ONFI) or the like.

### 1.1.2 Configuration of Memory Device

With reference to the block diagram shown in FIG. 1, the internal configuration of the memory device according to the first embodiment will be described. The memory device 3 includes, for example, a memory cell array 10, a command register 11, an address register 12, a sequencer 13, a driver module 14, a row decoder module 15 and a sense amplifier module 16.

The memory cell array 10 includes a plurality of blocks BLK0 to BLKn (n is an integer of one or more). The number of blocks BLK included in the memory cell array 10 may be one. The block BLK is a set of memory cells. The block BLK is used, for example, as a data erase unit. The memory cell array 10 is provided with a plurality of bit lines and a plurality of word lines. Each of the memory cells is associated with, for example, one bit line and one word line. The configuration of the memory cell array 10 will be described in detail later.

The command register 11 stores a command CMD that the memory device 3 has received from the memory controller 2. The command CMD includes, for example, an instruction for causing the sequencer 13 to perform a read operation, a write operation, an erase operation, and the like.

The address register 12 stores address information ADD that the memory device 3 has received from the memory controller 2. The address information ADD includes, for example, a block address BAd, a page address PAd and a column address CAd. For example, the block address BAd, page address PAd and column address CAd are used to select a block BLK, a word line and a bit line, respectively.

The sequencer 13 controls the operation of the entire memory device 3. In response to the command CMD stored in the command register 11, for example, the sequencer 13 controls the driver module 14, the row decoder module 15, the sense amplifier module 16, and the like to perform a read operation, a write operation, an erase operation, and the like.

The driver module 14 generates voltages for use in the read operation, the write operation, the erase operation, and the like. Then, based on, for example, the page address PAd stored in the address register 12, the driver module 14 applies the generated voltage to a signal line corresponding to the selected word line.

Based on the block address BAd stored in the address register 12, the row decoder module 15 selects a corresponding block BLK in the memory cell array 10. Then, the row decoder module 15 transfers, for example, the voltage which is applied to a signal line corresponding to the selected word line, to the selected word line in the selected block BLK.

In a write operation, the sense amplifier module 16 receives write data DAT from the memory controller 2 and applies a desired voltage to each bit line in accordance with the write data DAT. In a read operation, the sense amplifier module 16 determines the data stored in the memory cell based on the voltage of the bit line and transfers a result of the determination to the memory controller 2 as read data DAT.

### 1.1.3 Memory Cell Array

Next is a description of a configuration of a memory cell array included in the memory device according to the first embodiment.

### 1.1.3.1 Circuit Configuration

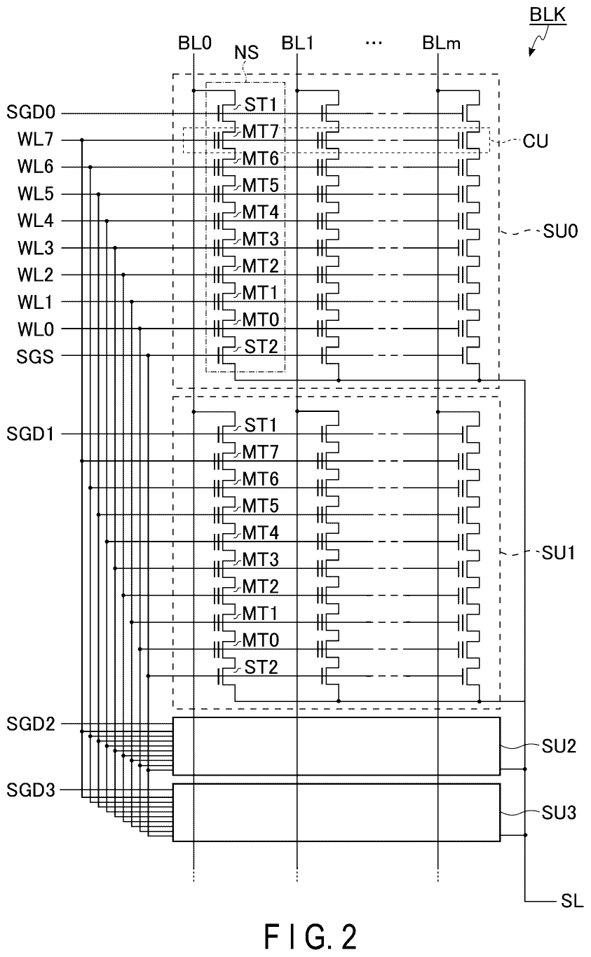

FIG. 2 is a circuit diagram showing an example of a circuit configuration of a memory cell array included in the memory device according to the first embodiment. In FIG. 2, one of the blocks BLK included in the memory cell array 10 is shown. As shown in FIG. 2, the block BLK includes four string units SU0 to SU3, for example.

Each string unit SU includes a plurality of NAND strings NS associated with their respective bit lines BL0 to BLm (m is an integer of one or more). The number of bit lines BL may be one. Each NAND string NS includes, for example, memory cell transistors MT0 to MT7 and selection transistors ST1 and ST2. Each memory cell transistor MT includes a control gate and a charge storage film to store data in a nonvolatile manner. Each of the selection transistors ST1 and ST2 is used to select a string unit SU in various operations.

In each NAND string NS, the memory cell transistors MT0 to MT7 are coupled in series. The drain of the selection transistor ST1 is coupled to the associated bit line BL. The source of the selection transistor ST1 is coupled to one end of the series-coupled memory cell transistors MT0 to MT7. The drain of the selection transistor ST2 is coupled to the other end of the series-coupled memory cell transistors. The source of the selection transistor ST2 is coupled to the source line SL.

In the same block BLK, the control gates of the memory cell transistors MT0 to MT7 are coupled to their respective word lines WL0 to WL7. The gates of the selection transistors ST1 in the string units SU0 to SU3 are coupled to their respective select gate lines SGD0 to SGD3. The gates of the selection transistors ST2 are coupled to the select gate line SGS.

Different column addresses are assigned to the bit lines BL0 to BLm. Each bit line BL is shared by NAND strings NS to which the same column address is assigned among the blocks BLK. Each of the word lines WL0 to WL7 is provided for each block BLK. The source line SL is shared among a plurality of blocks BLK, for example.

A set of memory cell transistors MT coupled to a common word line WL in a single string unit SU is called, for example, a cell unit CU. For example, the storage capacity of a cell unit CU including memory cell transistors MT each storing one-bit data is defined as “one-page data.” The cell unit CU may have a storage capacity of data of two or more pages in accordance with the number of bits of data stored in the memory cell transistor MT.

Note that the circuit configuration of the memory cell array 10 included in the memory device 3 according to the first embodiment is not limited to the configuration described above. For example, the number of string units SU included in each block BLK may be optional. The number of memory cell transistors MT included in each NAND string NS can be optional, as can be the number of selection transistors ST1 and ST2 included therein.

### 1.1.3.2 Planar Layout

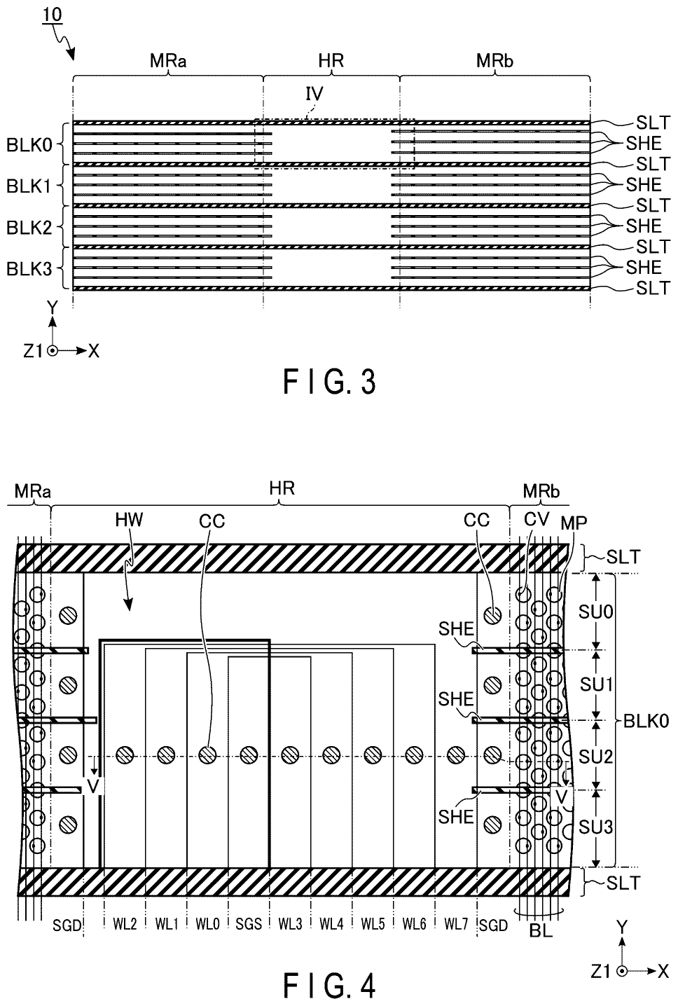

FIG. 3 is a plan view showing an example of a planar layout of a memory cell array included in the memory device according to the first embodiment. In FIG. 3, four blocks BLK0 to BLK3 are exemplified out of a plurality of blocks BLK included in the memory cell array 10.

The memory cell array 10 has a stacked wiring structure. The stacked wiring structure is a structure in which wiring layers (word lines WL0 to WL7 and select gate lines SGD and SGS) are stacked.

Hereinafter, a plane that is substantially parallel to the stacked plane of each of the wiring layers will be referred to as an XY plane. On the XY plane, directions that are orthogonal to each other will be defined as an X direction and a Y direction. In addition, a direction from the select gate line SGS toward the select gate line SGD, which is substantially perpendicular to the XY plane, will be defined as a Z1 direction, and a direction from the select gate line SGD toward the select gate line SGS, which is substantially perpendicular to the XY plane, will be defined as a Z2 direction. Unless the Z1 and Z2 directions are distinguished from each other, they will be indicated as a Z direction.

As shown in FIG. 3, the stacked wiring structure includes memory regions MRa and MRb and a hookup region HR arranged in the X direction. The memory regions MRa and MRb are regions where the memory cell transistors MT are provided. The hookup region HR is a region where a contact is provided to couple each wiring layer and the row decoder module 15 electrically. The hookup region HR is located, for example, between the memory regions MRa and MRb.

Each of the blocks BLK includes a portion of the stacked wiring structure which extends in the X direction across the memory region MRa, hookup region HR, and memory region MRb. The blocks BLK are arranged in the Y direction. The memory cell array 10 includes, for example, a plurality of members SLT and a plurality of members SHE.

Each member SLT extends in the X direction across the memory region MRa, hookup region HR, and memory region MRb. The members SLT are arranged in the Y direction. Each member SLT has, for example, a structure in which an insulator is embedded. Each member SLT separates adjacent wiring layers with the member SLT therebetween. In the memory cell array 10, each of the layers separated by the member SLT corresponds to one block BLK.

The members SHE include a plurality of members SHE arranged in the Y direction in the memory region MRa and a plurality of members SHE arranged in the Y direction in the memory region MRb. Each of the members SHE located in the memory region MRa extends in the X direction across the memory region MRa. Each of the members SHE located in the memory region MRb extends in the X direction across the memory region MRb. In the example of FIG. 3, three members SHE are arranged between two members SLT adjacent in the Y direction in each of the memory regions MRa and MRb. Each member SHE has, for example, a structure in which an insulator is embedded. Each member SHE separates the select gate lines SGD of wiring layers that are adjacent with the member SHE therebetween. In the memory cell array 10, each of the regions separated by a pair of adjacent members SLT and SHE or a pair of two adjacent members SHE corresponds to one string unit SU.

Note that the memory cell array 10 may have a layout other than the planar layout described above. For example, the number of members SHE located between two adjacent members SLT may be optional. The number of string units SU included in each block BLK may be varied based on the number of members SHE located between two adjacent members SLT.

FIG. 4 is a plan view showing an example of region IV of FIG. 3 in the planar layout of the memory cell array included in the memory device according to the first embodiment. FIG. 4 illustrates a hookup region HR and boundary portions between the hookup region HR and each of the memory regions MRa and MRb in the block BLK0.

First is a description of the planar layout of the memory cell array 10 in the memory regions MRa and MRb.

As shown in FIG. 4, the memory cell array 10 includes a plurality of memory pillars MP, a plurality of contacts CV and a plurality of bit lines BL in each of the memory regions MRa and MRb.

Each memory pillar MP functions as one NAND string NS. The memory pillars MP are arranged in a staggered shape of, e.g., 19 rows in a region between two adjacent members SLT. For example, viewed in the Z direction, one member SHE is superposed on each of the memory pillars MP in the fifth row, the memory pillars MP in the tenth row, and the memory pillars MP in the fifteenth row, from the upper side of the drawing sheet.

The bit lines BL are arranged in the X direction. Each bit line BL is located to overlap at least one memory pillar MP for each string unit SU. In the example of FIG. 4, two bit lines BL are superposed on one memory pillar MP. The memory pillar MP is electrically coupled via a contact CV to one of the bit lines BL superposed on one on another. On the other hand, a contact CV between the bit line BL and the memory pillar MP which is in contact with two different select gate lines SGD (or which is overlapped with the member SHE) may be omitted.

The memory cell array 10 in the memory region MR may have a layout other than the planar layout described above. For example, the number and arrangement of memory pillars MP and members SHE located between two adjacent members SLT may be changed as appropriate. The number of bit lines BL that overlap each memory pillar MP may be optional.

Next is a description of the planar layout of the memory cell array 10 in the hookup region HR.

The memory cell array 10 includes a plurality of contacts CC in the hookup region HR. The stacked wiring structure includes a terrace portion and a highway portion HW in the hookup region HR. The terrace portion is a portion where the wiring layers of the stacked wiring structure do not overlap with an upper wiring layer in the Z1 direction. The highway portion HW is aligned with the terrace portion in the Y direction.

The stacked wiring structure has a staircase structure in the terrace portion. In the example of FIG. 4, steps are formed between the select gate line SGS and the word line WL0, between the word line WL0 and the word line WL1, . . . , between the word line WL6 and the word line WL7, and between the word line WL7 and the select gate line SGD. Not all of the steps need to be aligned in one direction. For example, some of the select gate line SGS and the word lines WL0 to WL7 (in the example of FIG. 4, select gate line SGS and word lines WL0 to WL2) may constitute steps in descending order in the X direction, and the remaining lines (in the example of FIG. 4, word lines WL3 to WL7) may constitute steps in ascending order in the X direction. In addition, for example, some of the select gate line SGS and the word lines WL0 to WL7 may constitute steps in the Y direction.

The wiring layers of the memory region MRa and those of the memory region MRb are continuously provided through the highway portion HW, except for the selection gate line SGD. That is, the highway portion HW is a portion that couples the wiring layers excluding the selection gate line SGD electrically between the memory regions MRa and MRb. The select gate line SGD is divided into a portion of the memory region MRa and a portion of the memory region MRb by the hookup region HR.

The contacts CC are conductors used for coupling between the row decoder module 15 and the wiring layers. The contacts CC associated with the blocks BLK are coupled to the respective terrace portions of the select gate lines SGS and SGD and word lines WL0 to WL7 which are provided in the hookup region HR. Different contacts CC are provided for the select gate line SGD alongside the memory region MRa and the select gate line SGD alongside the memory region MRb. The select gate line SGD alongside the memory region MRa and the select gate line SGD alongside the memory region MRb, which are associated with the same string unit SU, are electrically coupled via, for example, their respective contacts CC and an upper wiring layer (not shown).

### 1.1.3.3 Sectional Structure

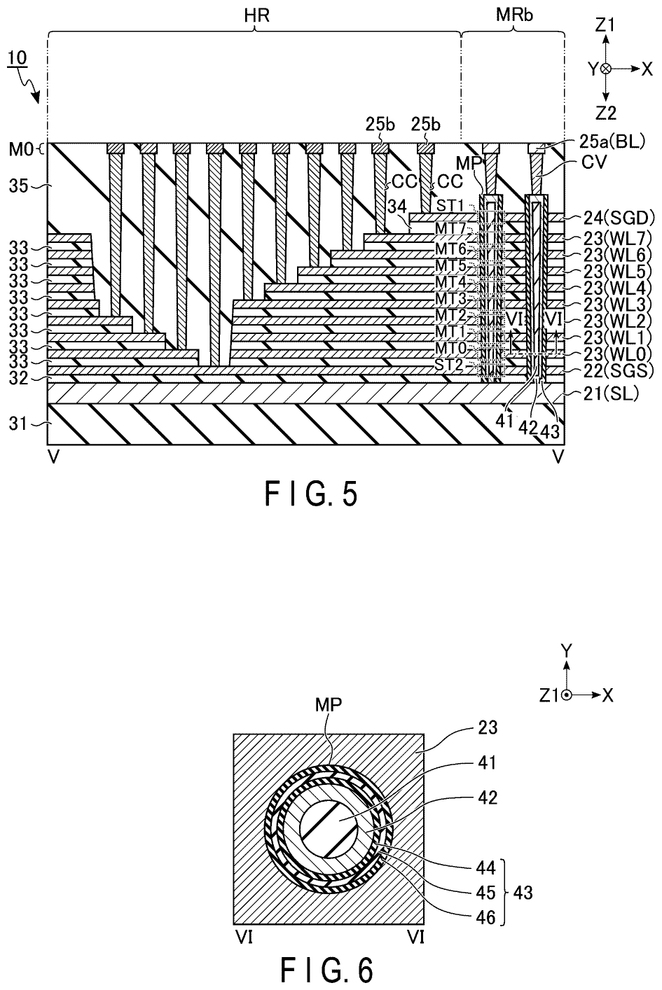

FIG. 5 is a cross-sectional view taken along line V-V of FIG. 4 and showing an example of a cross-sectional structure of the memory cell array included in the memory device according to the first embodiment. In FIG. 5, a cross-sectional structure of part of each of the memory region MRb and hookup region HR is shown.

As shown in FIG. 5, the memory cell array 10 includes, for example, a semiconductor layer 21, wiring layers 22, 23 and 24, a conductor layer 25 (25a and 25b), and insulator layers 31, 32, 33, 34 and 35. The insulator layers 31 to 35 contain silicon oxide, for example. In FIG. 5, the Z1 direction corresponds to the upper side of the drawing sheet.

The semiconductor layer 21 is provided on the insulator layer 31. The semiconductor layer 21 is formed, for example, in a plate shape extending along the XY plane. The semiconductor layer 21 contains, for example, silicon and is used as a source line SL.

The insulator layer 32 is provided on the semiconductor layer 21. The wiring layer 22 is provided on the insulator layer 32. The wiring layer 22 is formed, for example, in a plate shape extending along the XY plane. The wiring layer 22 contains, for example, tungsten and is used as a select gate line SGS.

A plurality of insulator layers 33 and a plurality of wiring layers 23 are provided alternately on the wiring layer 22. The wiring layers 23 are formed, for example, in a plate-like shape extending along the XY plane. The wiring layers 23 contain, for example, tungsten and are used as word lines WL0 to WL7 in order from the semiconductor layer 21.

The insulator layer 34 is provided on the topmost wiring layer 23. The wiring layer 24 is provided on the insulator layer 34. The wiring layer 24 is formed, for example, in a plate shape extending along the XY plane. The wiring layer 24 contains, for example, tungsten and is used as a select gate line SGD.

In the memory region MRb, each of the memory pillars MP extends in the Z direction and penetrates the wiring layers 22 to 24 and insulator layers 32 to 34. Each of the memory pillars MP has, for example, a shape whose diameter decreases (tapers) in the Z2 direction. Although not shown in FIG. 5, a plurality of memory pillars MP are provided in the memory region MRa in the same manner.

Each of the memory pillars MP includes, for example, a core film 41, a semiconductor film 42 and a stacked film 43. The core film 41 is an insulator extending in the Z direction. The semiconductor film 42 covers the core film 41. The lower part of the semiconductor film 42 is in contact with the semiconductor layer 21. The stacked film 43 covers the side surface of the semiconductor film 42.

FIG. 6 is a cross-sectional view taken along line VI-VI of FIG. 5 and showing an example of a cross-sectional structure of a memory pillar included in the memory device according to the first embodiment. The cross section of FIG. 6 includes the memory pillar MP and the wiring layer 23 and is parallel to the XY plane. As shown in FIG. 6, the stacked film 43 includes, for example, a tunnel insulating film 44, a charge storage film 45, and a block insulating film 46.

The core film 41 is provided, for example, in a central part of the memory pillar MP. The semiconductor film 42 surrounds the core film 41. The tunnel insulating film 44 surrounds the semiconductor film 42. The charge storage film 45 surrounds the tunnel insulating film 44. The block insulating film 46 surrounds the charge storage film 45. The wiring layer 23 surrounds the block insulating film 46. The semiconductor film 42 is used as a channel (current path) of the memory cell transistors MT0 to MT7 and select transistors ST1 and ST2. Each of the tunnel insulating film 44 and block insulating film 46 contains, for example, silicon oxide. The charge storage film 45 contains, for example, silicon nitride.

With the above configuration, each of the memory pillars MP functions as one NAND string NS. That is, a portion where the memory pillar MP and the wiring layer 22 intersect functions as a selection transistor ST2. A portion where the memory pillar MP and the wiring layer 23 intersect functions as a memory cell transistor MT. A portion where the memory pillar MP and the wiring layer 24 intersect functions as a selection transistor ST1.

The contact CV is provided on the upper surface of the semiconductor film 42 in the Z1 direction in the memory pillar MP. The contact CV has, for example, a shape whose diameter tapers in the Z2 direction. A conductive layer 25a is provided on the upper surface of the contact CV in the Z1 direction. The conductive layer 25a is formed, for example, in a line shape extending in the Y direction. The conductive layer 25a contains, for example, copper and is used as a bit line BL.

In the hookup region HR, each of the contacts CC extends in the Z direction. Each of the contacts CC has, for example, a shape whose diameter tapers in the Z2 direction. The contacts CC are provided in contact with the terrace portions of the corresponding wiring layer 22 to 24 and apart from the wiring layers 22 to 24 not corresponding to the contacts CC.

The conductive layer 25b is provided on the upper surface of the contact CC in the Z1 direction. The conductor layer 25b contains, for example, copper and is provided in the same layer as the conductor layer 25a. Hereinafter, the layer provided with the conductor layers 25a and 25b will be referred to as a layer M0.

The insulator layer 35 is provided to cover the stacked wiring structure, contacts CC and CV, and conductive layers 25a and 25b.

### 1.1.4 Configuration of Memory Device

Next is a description of a configuration of the memory device according to the first embodiment.

### 1.1.4.1 Bonding Structure

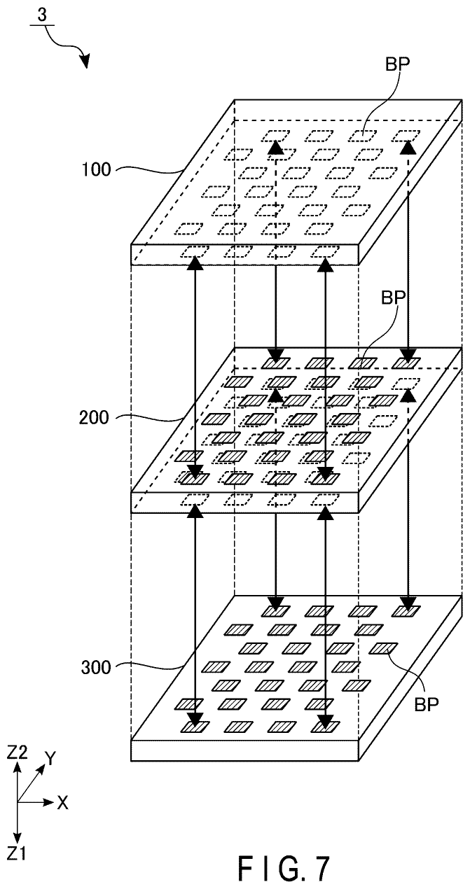

FIG. 7 is a perspective view showing an outline of a bonding structure of the memory device according to the first embodiment. As shown in FIG. 7, the memory device 3 includes a memory chip 100 and circuit chips 200 and 300. The memory chip 100 has a structure corresponding to the memory cell array 10. The circuit chips 200 and 300 each have a structure corresponding to, for example, the command register 11, address register 12, sequencer 13, driver module 14, row decoder module 15, and sense amplifier module 16. A transistor having a relatively low breakdown voltage (low breakdown voltage transistor) is mainly formed in the circuit chip 200. A transistor having a relatively high breakdown voltage (high breakdown voltage transistor) is mainly formed in the circuit chip 300. As an example, the circuit chip 200 may include, for example, the command register 11, address register 12, sequencer 13 and sense amplifier module 16. The circuit chip 300 may include, for example, the driver module 14 and row decoder module 15.

The high breakdown voltage transistor is also called an HV transistor and its gate insulating film has a thickness of at least 10 nm or more. If the transistor can operate up to 30 V, it is designed such that the thickness of the gate insulating film is, for example, about 40 nm. The low breakdown voltage transistor includes an LV transistor and a VLV transistor. The LV transistor is designed so that the thickness of the gate insulating film is, for example, 5 nm or more and 7 nm or less. The VLV transistor is designed so that the thickness of the gate insulating film is 2.5 nm or more and 3.5 nm or less.

Each of the memory chip 100 and circuit chips 200 and 300 includes a plurality of bonding pads BP. The memory device 3 is formed by bonding the memory chip 100 and circuit chip 200 and bonding the circuit chip 200 and circuit chip 300 via a plurality of bonding pads BP. That is, the circuit chip 200 is provided between the memory chip 100 and the circuit chip 300. The surface of the circuit chip 200 in the Z1 direction is bonded to the circuit chip 300, and the surface of the circuit chip 200 in the Z2 direction is bonded to the memory chip 100.

### 1.1.4.2 Cross-Sectional Structure

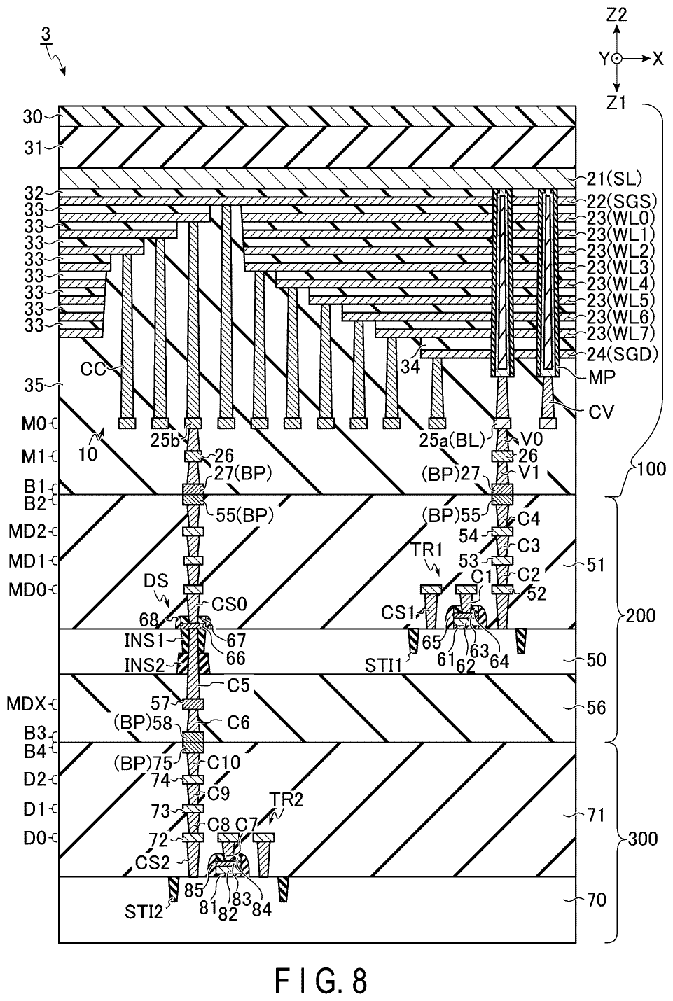

FIG. 8 is a cross-sectional view showing an example of a cross-sectional structure of the memory device according to the first embodiment. In FIG. 8, the Z2 direction corresponds to the upper side of the drawing sheet.

As shown in FIG. 8, the memory chip 100 of the memory device 3 includes conductive layers 26 and 27, a protective layer 30, and contacts V0 and V1. The circuit chip 200 of the memory device 3 includes a substrate 50, insulator layers 51 and 56, conductor layers 52, 53, 54, 55, 57 and 58, insulating members STI1, INS1 and INS2, a transistor TR1, a member DS, and contacts CS0, CS1, C1, C2, C3, C4, C5 and C6. The circuit chip 300 of the memory device 3 includes a substrate 70, an insulator layer 71, conductive layers 72, 73, 74 and 75, an insulating member STI2, a transistor TR2, and contacts CS2, C7, C8, C9 and C10.

First, the memory chip 100 will be described.

The protective layer 30 is provided on the upper surface of the insulator layer 31 in the Z2 direction. The protective layer 30 corresponds to the surface of the memory device 3 and contains, for example, a resin material such as polyimide. The protective layer 30 is partly removed from a region not shown. The region is provided with a power supply pad for electrical connection with an external device.

The contact V0 is provided on the upper surface of each of the conductor layers 25a and 25b in the Z1 direction. The contact V0 has, for example, a shape whose diameter tapers in the Z2 direction. The conductor layer 26 is provided on the upper surface of the contact V0 in the Z1 direction.

The contact V1 is provided on the upper surface of the conductor layer 26 in the Z1 direction. The contact V1 has, for example, a shape whose diameter tapers in the Z2 direction. The conductor layer 27 is provided on the upper surface of the contact V1 in the Z1 direction. The conductor layer 27 functions as a bonding pad BP on the bonding surface of the memory chip 100 and the circuit chip 200. The conductor layers 26 and 27 and contacts V0 and V1 are covered by the insulator layer 35. Hereinafter, the layers provided with the conductor layers 26 and 27 will be referred to as a layer M1 and a bonded layer B1, respectively.

Next, the circuit chip 200 will be described.

The substrate 50 is a silicon substrate. The substrate 50 has a thickness of, for example, 500 nanometers (nm) or more and 2000 nm or less. The insulator layer 51 is provided on the upper surface of the substrate 50 in the Z2 direction. The insulating members STI1 and INS1 are provided in the surface of the substrate 50 in the Z2 direction. The insulating member INS2 is provided in the surface of the substrate 50 in the Z1 direction. The substrate 50 and the insulator layer 51 are provided with the transistor TR1 and the member DS.

The insulating member STI1 is placed so as to surround the transistor TR1. The upper surface of the insulating member STI1 in the Z2 direction is flush with, for example, the upper surface of the substrate 50 in the Z2 direction. The lower surface of the insulating member STI1 in the Z2 direction is located inside the substrate 50, for example. The insulating member STI1 has a long columnar portion in one direction (in the Y direction in the example of FIG. 8) in the XY plane and has, for example, a shape whose diameter tapers in the Z1 direction. The insulating member STI1 includes, for example, silicon oxide.

The transistor TR1 is a component of a variety of circuits provided in the circuit chip 200. The transistor TR1 includes, for example, a gate insulating film 61, conductive films 62 and 63, and insulating films 64 and 65.

The gate insulating film 61 is provided on the upper surface of the substrate 50 in the Z2 direction. The gate insulating film 61 contains, for example, silicon oxide. The breakdown voltage of the transistor TR1 is regulated in accordance with the thickness of the gate insulating film 61.

The conductive film 62 is provided on the upper surface of the gate insulating film 61 in the Z2 direction. The conductive film 63 is provided on the upper surface of the conductive film 62 in the Z2 direction. The conductive film 62 contains, for example, polysilicon. The conductive film 63 includes, for example, a stacked film in which titanium, titanium nitride and tungsten are stacked in the order presented in the Z2 direction. The conductive films 62 and 63 function as a gate electrode of the transistor TR1.

The insulating film 64 is provided on the upper surface of the conductive film 63 in the Z2 direction. The insulating film 64 contains, for example, silicon nitride. The insulating film 65 covers the side surfaces of the gate insulating film 61, conductive films 62 and 63, and insulating film 64. The insulating film 65 contains, for example, silicon oxide.

The insulating member INS1 is distributed, for example, in a region where the transistor TR1 is not provided. The upper surface of the insulating member INS1 in the Z2 direction is flush with, for example, the upper surface of the substrate 50 in the Z2 direction. The lower surface of the insulating member INS1 in the Z2 direction is located inside the substrate 50, for example. The insulating member INS1 has a columnar portion which is substantially square when viewed in the Z direction, and has a shape whose diameter tapers in the Z1 direction. Like the insulating member STI1, the insulating member INS1 may have a long columnar portion in one direction in the XY plane. The insulating member INS1 contains, for example, silicon oxide.

The member DS has a structure that suppresses polishing unevenness (dishing) generated in a polishing step executed in manufacturing the transistor TR1. The member DS includes, for example, a conductive film 66 and insulating films 67 and 68.

The conductive film 66 is provided on the upper surface of the insulating member INS1 in the Z2 direction. The conductive film 66 includes a stacked film in which, for example, titanium, titanium nitride and tungsten are stacked in this order in the Z2 direction. The thickness of the conductive film 66 is substantially equal to that of the conductive film 63. The distance between the upper surface of the substrate 50 in the Z2 direction and that of the conductive film 66 in the Z2 direction is equal to or shorter than the distance between the upper surface of the substrate 50 in the Z2 direction and that of the conductive film 63 in the Z2 direction. In order to suppress the dishing described above, the ratio (coverage) of the conductive films 63 and 66 to the substrate 50 is designed to be equal to or greater than a predetermined threshold value when viewed in the Z1 direction.

The insulating film 67 is provided on the upper surface of the conductive film 66 in the Z2 direction. The insulating film 67 contains, for example, silicon nitride. The thickness of the insulating film 67 is substantially equal to that of the insulating film 64.

The insulating film 68 covers the side surfaces of the conductive film 66 and the insulating film 67. The insulating film 68 contains, for example, silicon oxide. The thickness of the insulating film 68 is substantially equal to that of the insulating film 65.

The contact C1 is provided on the upper surface of the conductive film 63 in the Z2 direction. The contact C1 extends in the Z2 direction through the insulating film 64. The contact CS1 is provided in the Z2 direction on the upper surface of a region of the substrate 50 which functions as the source or drain of the transistor TR1. The contact CS0 is provided on the upper surface of the conductive film 66 in the Z2 direction. A height of the upper surface of the conductive film 66 in the Z2 direction is lower than that of the conductive film 63 in the Z2direction. The contacts CS0 and C1 extend in the Z2direction on their respective upper surfaces of the conductive films 66 and 63 in the Z2 direction, and reach a height equivalent to the upper surface of the contact CS1 in the Z2 direction. Each of the contacts C1, CS0 and CS1 has, for example, a shape whose diameter tapers in the Z1 direction. The conductive layer 52 is provided on the upper surface of each of the contacts C1, CS0 and CS1 in the Z2 direction. The contacts C1, CS0 and CS1 and the conductor layer 52 contain, for example, tungsten.

The contact C2 is provided on the upper surface of the conductive layer 52 in the Z2 direction. The conductive layer 53 is provided on the upper surface of the contact C2 in the Z2 direction. The contact C3 is provided on the upper surface of the conductor layer 53 in the Z2 direction. The conductive layer 54 is provided on the upper surface of the contact C3 in the Z2 direction. The contact C4 is provided on the upper surface of the conductor layer 54 in the Z2 direction. The conductor layer 55 is provided on the upper surface of the contact C4 in the Z2 direction. Each of the contacts C2, C3 and C4 extends in the Z2 direction and has a shape whose diameter tapers in the Z1 direction. The conductor layer 55 is in contact with its corresponding conductor layer 27 and functions as a bonding pad BP on the bonding surface of the circuit chip 200 and the memory chip 100. The conductor layers 52, 53, 54 and 55 and the contacts CS0, CS1, C1, C2, C3 and C4 are covered with the insulator layer 51. Hereinafter, the layers provided with the conductor layers 52, 53, 54 and 55 will be referred to as layers MD0, MD1 and MD2 and a bonding layer B2, respectively.

The insulating member INS2 is provided on the lower surface of the insulating member INS1 in the Z2 direction. The upper surface of the insulating member INS2 in the Z2 direction is in contact with the insulating member INS1. The lower surface of the insulating member INS2 in the Z2 direction is flush with, for example, the lower surface of the substrate 50 in the Z2 direction. The insulating member INS2 has a columnar portion which is substantially square when viewed in the Z direction. Like the insulating member INS1, the insulating member INS2 may have a long columnar portion in one direction in the XY plane. The insulating member INS2 has a shape whose diameter tapers in the Z2 direction. That is, the taper direction of the insulating member INS2 is opposite to that of the insulating members STI1 and INS1 in the Z direction. The insulating member INS2 contains, for example, silicon oxide.

The insulator layer 56 is provided on the lower surface of the substrate 50 in the Z2 direction. The insulator layer 56 contains, for example, silicon oxide.

The contact C5 is provided on the lower surface of the conductive film 66 in the Z2 direction. The contact C5 extends in the Z1 direction through the insulating members INS1 and INS2, and has a shape whose diameter tapers in the Z2 direction. The lower surface of the contact C5 in the Z2 direction reaches a position within the insulator layer 56. The conductor layer 57 is provided on the lower surface of the contact C5 in the Z2 direction. The contact C5 and the conductive layer 57 contain, for example, copper or tungsten.

The contact C6 is provided on the lower surface of the conductor layer 57 in the Z2 direction. The contact C6 extends in the Z1 direction and has a shape whose diameter tapers in the Z2 direction. The conductor layer 58 is provided on the lower surface of the contact C6 in the Z2 direction. The contact C6 and the conductor layer 58 contain, for example, copper. The conductor layers 57 and 58 and contacts C5 and C6 are covered with the insulator layer 56. The conductor layer 58 functions as a bonding pad BP on the bonding surface of the circuit chip 200 and the circuit chip 300. Hereinafter, the layers provided with the conductor layers 57 and 58 will be referred to as a layer MDX and a bonding layer B3, respectively.

Next, the circuit chip 300 will be described.

The substrate 70 is a silicon substrate. The substrate 70 has a thickness that is, for example, equal to or greater than that of the substrate 50. The insulator layer 71 is provided on the upper surface of the substrate 70 in the Z2 direction. The insulating member STI2 is provided in the surface of the substrate 70 in the Z2 direction. The substrate 70 and the insulator layer 71 are provided with the transistor TR2.

The insulating member STI2 is located to surround the transistor TR2. The upper surface of the insulating member STI2 in the Z2 direction is flush with, for example, the upper surface of the substrate 70 in the Z2 direction. The lower surface of the insulating member STI2 in the Z2 direction is located inside the substrate 70, for example. The insulating member STI2 has a long columnar portion in one direction (in the example of FIG. 8, the Y direction) in the XY plane and has, for example, a shape whose diameter tapers in the Z1 direction. The insulating member STI2 contains, for example, silicon oxide.

The transistor TR2 is a component of a variety of circuits provided in the circuit chip 300. The transistor TR2 includes, for example, a gate insulating film 81, conductive films 82 and 83, and insulating films 84 and 85.

The gate insulating film 81 is provided on the upper surface of the substrate 70 in the Z2 direction. The gate insulating film 81 contains, for example, silicon oxide. The breakdown voltage of the transistor TR2 is regulated in accordance with the thickness of the gate insulating film 81.

The conductive film 82 is provided on the upper surface of the gate insulating film 81 in the Z2 direction. The conductive film 83 is provided on the upper surface of the conductive film 82 in the Z2 direction. The conductive film 82 contains, for example, polysilicon. The conductive film 83 includes a stacked film in which, for example, titanium, titanium nitride and tungsten are stacked in this order in the Z2 direction. The conductive films 82 and 83 function as a gate electrode of the transistor TR2.

The insulating film 84 is provided on the upper surface of the conductive film 83 in the Z2 direction. The insulating film 84 contains, for example, silicon nitride. The insulating film 85 covers the side surfaces of the gate insulating film 81, conductive films 82 and 83, and insulating film 84. The insulating film 85 contains, for example, silicon oxide.

The contact C7 is provided on the upper surface of the conductive film 83 in the Z2 direction. The contact C7 extends in the Z2 direction through the insulating film 84. The contact CS2 is provided in the Z2 direction on the upper surface of a region of the substrate 70 which functions as the source or drain of the transistor TR2. The contact CS2 extends in the Z2 direction and reaches a height equivalent to the upper surface of the contact C7 in the Z2 direction. Each of the contacts C7 and CS2 has a shape whose diameter tapers in the Z1 direction. The conductive layer 72 is provided on the upper surface of each of the contacts C7 and CS2 in the Z2 direction.

The contact C8 is provided on the upper surface of the conductor layer 72 in the Z2 direction. The conductor layer 73 is provided on the upper surface of the contact C8 in the Z2 direction. The contact C9 is provided on the upper surface of the conductor layer 73 in the Z2 direction. The conductor layer 74 is provided on the upper surface of the contact C9 in the Z2 direction. The contact C10 is provided on the upper surface of the conductor layer 74 in the Z2 direction. The conductor layer 75 is provided on the upper surface of the contact C10 in the Z2 direction. Each of the contacts C8, C9 and C10 extends in the Z2 direction and has a shape whose diameter tapers in the Z1 direction. The conductor layer 75 is in contact with its corresponding conductor layer 58 and functions as a bonding pad BP on the bonding surface of the circuit chip 300 and the circuit chip 200. The conductor layers 72, 73, 74 and 75 and the contacts CS2, C7, C8, C9 and C10 are covered with the insulator layer 71. Hereinafter, the layers provided with the conductor layers 72, 73, 74 and 75 will be referred to as layers D0, D1 and D2 and a bonding layer B4, respectively.

### 1.1.4.3 Bonding Pad

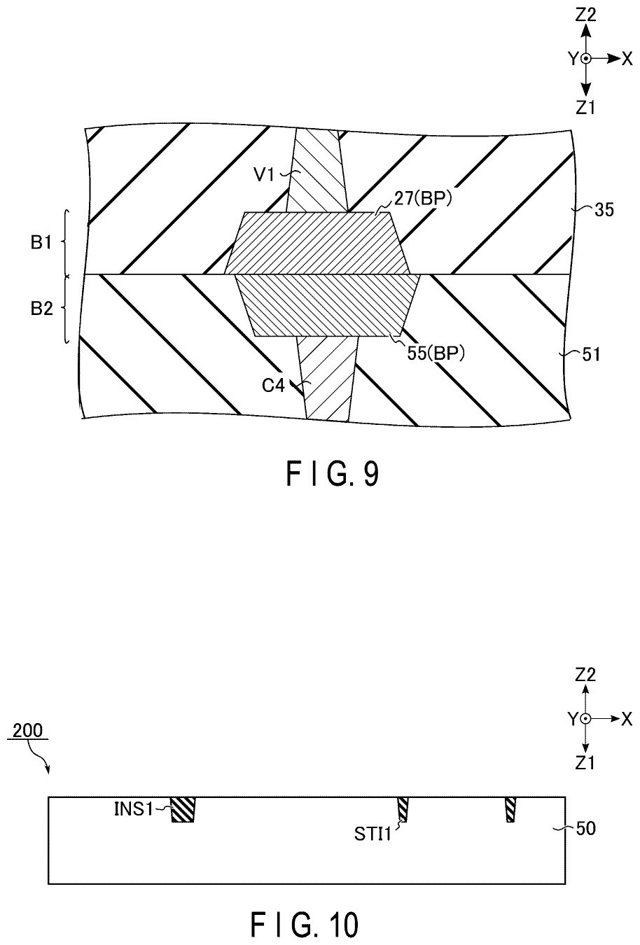

FIG. 9 is a cross-sectional view showing an example of a cross-sectional structure of a bonding pad included in the memory device according to the first embodiment. In the example of FIG. 9, the conductor layers 27 and 55 and contacts V1 and C4 are provided on the bonded surface of the memory chip 100 and the circuit chip 200. Note that the configuration of the bonding surface of the circuit chip 200 and the circuit chip 300 (not shown) is the same as that of the bonding surface of the memory chip 100 and the circuit chip 200 shown in FIG. 9.

As shown in FIG. 9, in the step of bonding the memory chip 100 and the circuit chip 200, the conductor layer 27 is connected to the conductor layer 55. In the example of FIG. 9, the areas of the conductor layers 27 and 55 on the bonded surface are substantially equal. If, in this case, copper is used for the conductor layers 27 and 55, the copper of the conductor layer 27 and that of the conductor layer 55 are integrated to make it difficult to confirm the boundary between the conductor layers. However, the bonding boundary can be confirmed by the distortion of bonding due to the positional displacement of the conductor layers 27 and 55 and by the positional displacement of a barrier metal of copper (by the discontinuity in the side surface).

When the conductor layers 27 and 55 are formed by the damascene method, the side surface of each of the layers has a tapered shape. Therefore, the sidewall of the bonding of the conductor layers 27 and 55 along the Z direction is not linear or the cross section thereof is not rectangular.

When the conductor layers 27 and 55 are bonded together, the bottom, side and top surfaces of copper forming the conductive layers are covered with barrier metal. In contrast, in a general wiring layer using copper, an insulator layer (silicon nitride, silicon carbonitride or the like) having an antioxidant function of copper is provided on the upper surface of the copper, and no barrier metal is provided. It is thus possible to distinguish the barrier metal layer from the general wiring layer even if no bonding positional displacement occurs between the conductor layers.

### 1.2 Manufacturing Method

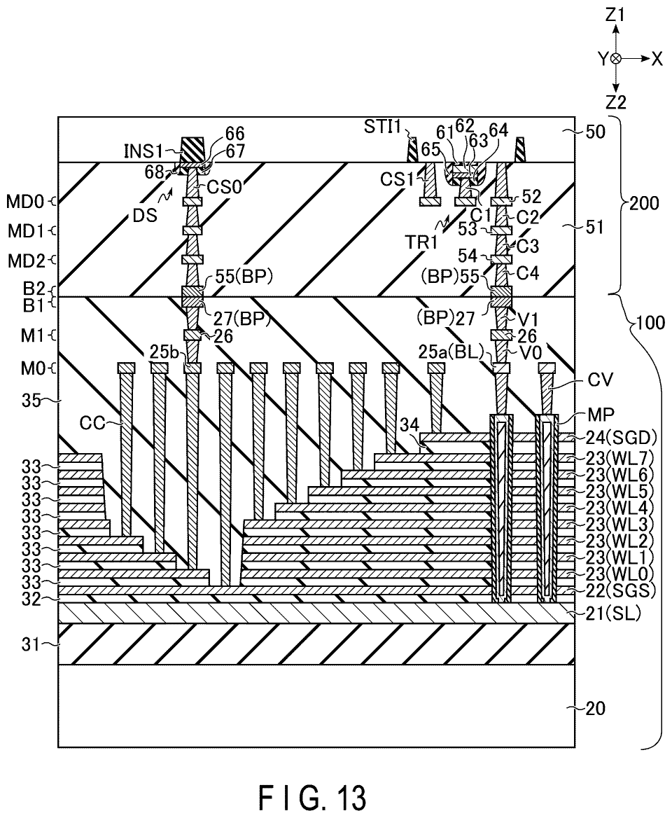

FIGS. 10 to 17 are cross-sectional views each showing an example of the cross-sectional structure of the memory device according to the first embodiment which is in the process of being manufactured. FIGS. 10 to 12 each correspond to a cross section of the circuit chip 200 which is in the process of being manufactured. FIGS. 13 to 17 each correspond to a cross section of the circuit chip 200 which is in the process of being manufactured after being bonded to the memory chip 100.

First, the memory chip 100, circuit chip 200 and circuit chip 300 are manufactured separately. Focusing on the circuit chip 200, as shown in FIG. 10, insulating members STI1 and INS1 are formed on the substrate 50. Specifically, by anisotropic etching, a groove is formed in a region on the upper surface of the substrate 50 in the Z2 direction where the insulating members STI1 and INS1 are to be formed. The groove has a shape whose diameter tapers in the Z1 direction. Then, the groove is filled with an insulating film to form the insulating members STI1 and INS1. As described above, the insulating members STI1 and INS1 are formed together and thus they have approximately the same film thickness.

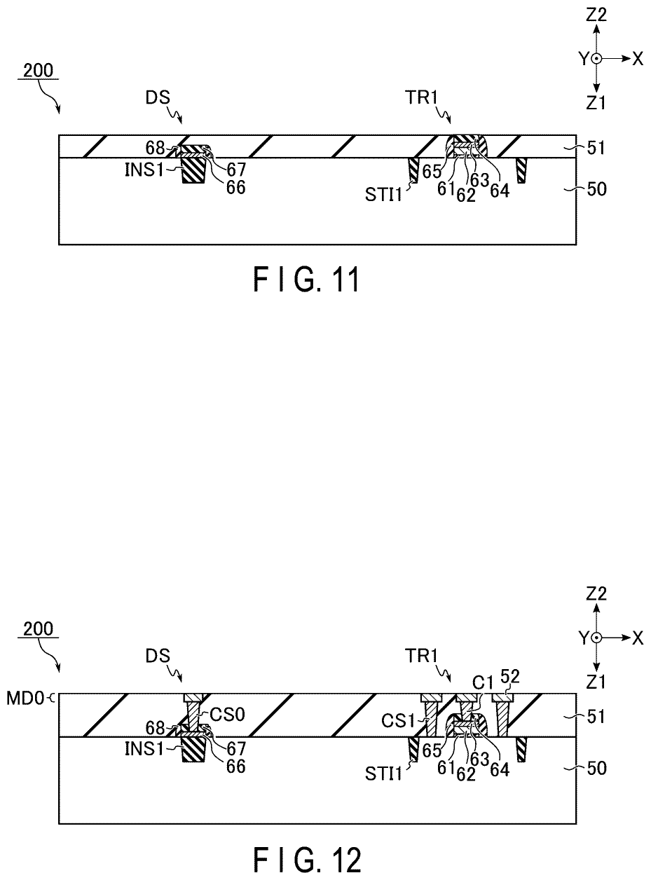

Next, as shown in FIG. 11, a transistor TR1 and a member DS are formed on the upper surface of the substrate 50 in the Z2 direction. Specifically, an insulating film containing silicon oxide and a conductive film containing polysilicon are stacked on the upper surface of the substrate 50 in the Z2 direction. Then, for example, by anisotropic etching, the stacked insulating film and conductive film are removed except for the region where the gate of the transistor TR1 is formed. Accordingly, the gate insulating film 61 and the conductive film 62 are formed. After that, a conductive film in which titanium, titanium nitride and tungsten are stacked and an insulating film containing silicon nitride are formed on the upper surface of the resultant structure in the Z2 direction. Then, for example, by anisotropic etching, the stacked conductive film and insulating film are removed except for the region where the gate of the transistor TR1 is formed and the region where the member DS is formed. Accordingly, the conductive films 63 and 66 and the insulating films 64 and 67 are formed. After that, insulating films 65 and 68 are formed on their respective side walls of the resultant structure. Thus, the conductive films 63 and 66 and the insulating films 64 and 67 are formed at once and thus they have approximately the same thickness.

Next, as shown in FIG. 12, a structure corresponding to the contacts C1, CS0 and CS1 and the layer MD0 is formed. The contact CS0 is located to overlap the conductive film 66 when viewed in the Z direction. Thus, the contact CS0 is not formed through the conductive film 66; accordingly, it does not reach the insulating member INS1. After that, a structure corresponding to the layers MD1 and MD2 and the bonding layer B2 is formed.

Next, as shown in FIG. 13, the bonding layer B1 of the memory chip 100 and the bonding layer B2 of the circuit chip 200 are bonded to each other. Note that when the memory chip 100 is bonded to the circuit chip 200, the memory cell array 10 is formed on the substrate 20. After they are bonded, the substrate 50 of the circuit chip 200 is polished to a thickness of, for example, 500 nm or more and 2000 nm or less.

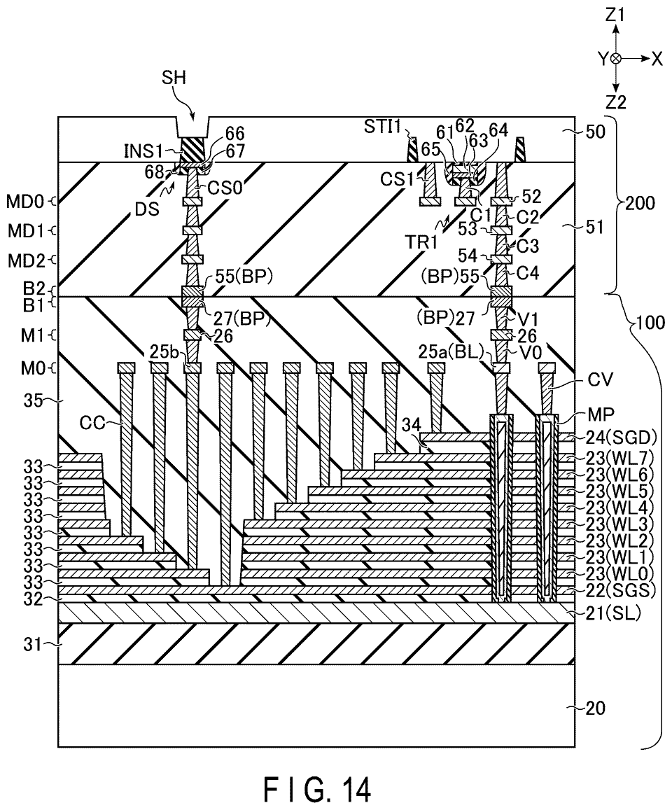

Next, as shown in FIG. 14, for example, by anisotropic etching, a groove SH is formed in a region on the upper surface of the substrate 50 in the Z1 direction where the insulating member INS2 is to be formed. Thus, the insulating member INS1 is exposed to the lower surface of the groove SH in the Z1 direction.

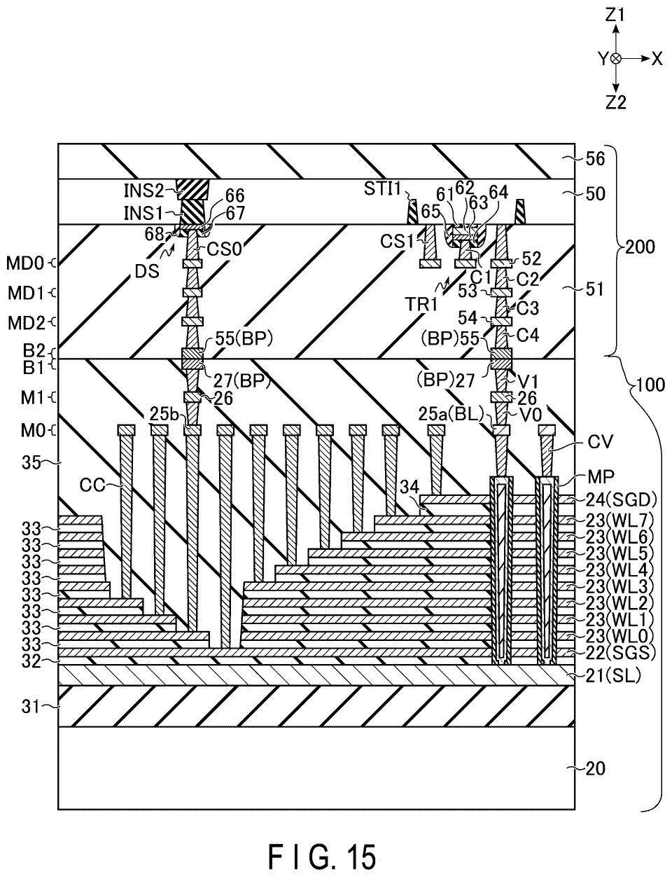

Next, as shown in FIG. 15, the insulator layer 56 is formed on the upper surface of the substrate 50 in the Z1direction to fill the groove SH and thus form the insulating member INS2.

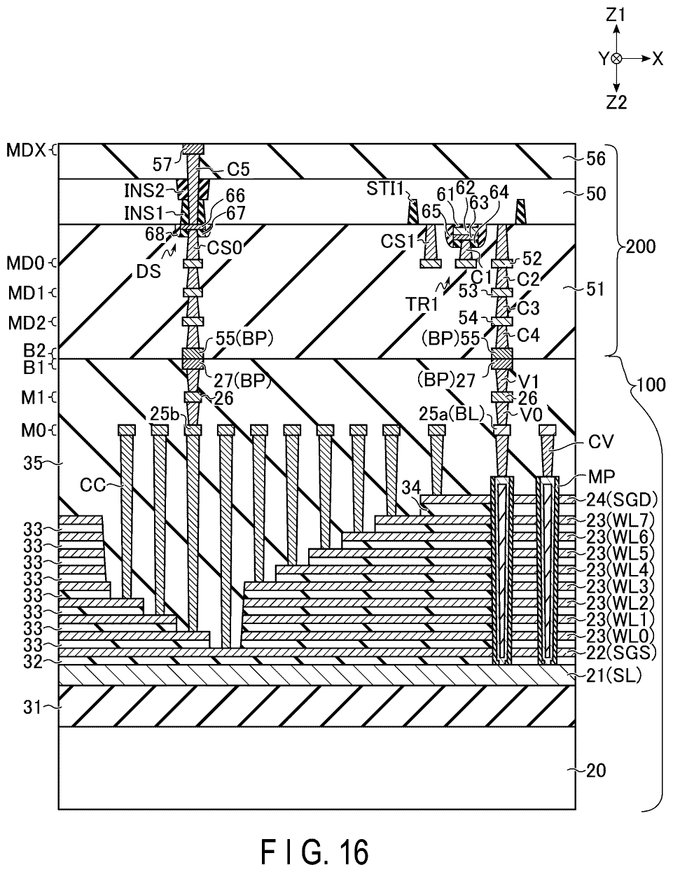

Next, as shown in FIG. 16, for example, by anisotropic etching, a contact C5 and a layer MDX are formed. Specifically, a hole is formed in a region on the upper surface of the insulator layer 56 in the Z1 direction where the contact C5 is to be formed. The hole is formed through the insulating members INS2 and INS1 and reaches the conductive film 66. The hole is filled with a sacrificial member, for example. On the upper surface of the sacrificial member in the Z1 direction, a region where the conductor layer 57 is to be formed is opened. The opening is formed to overlap the hole filled with the sacrificial member and have a diameter that is larger than that of the hole when viewed in the Z direction. After the sacrificial member is removed, the contact C5 and conductor layer 57 are formed to fill the hole and opening. The contact C5 and the conductor layer 57 may contain tungsten or copper.

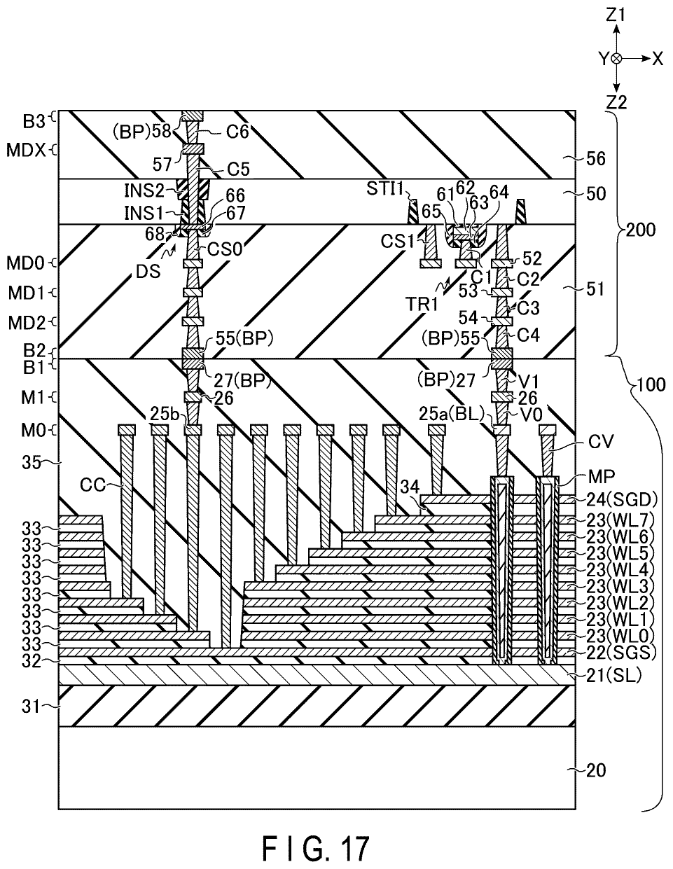

Next, as shown in FIG. 17, the contact C6 and the bonding layer B3 are formed. The contact C6 and the conductor layer 58 contain copper.

The bonding layer B3 of the circuit chip 200 and the bonding layer B4 of the circuit chip 300 are bonded to each other. After the substrate 20 of the memory chip 100 is removed, a power supply pad, a protective layer 30, and the like are formed. Thus, the memory device 3 is formed.

### 1.3 Advantageous Effects of First Embodiment

According to the first embodiment, the conductive film 66 is provided on the surface of the substrate 50 on the stacked wiring structure side. The contact CS0 extends in the Z2 direction on the stacked wiring structure side from the conductive film 66 and is brought into contact with the conductive film 66. The contact C5 extends in the Z2 direction to cross the substrate 50 alongside the substrate 70 from the conductive film 66 and is brought into contact with the conductive film 66. Thus, a structure for electrical connection between the memory chip 100 and the circuit chip 300 can be achieved by utilizing a region where the member DS is formed to suppress dishing in the process of manufacturing the transistor TR1. It is therefore possible to improve the integration efficiency of the memory device 3.

The insulating member INS1 is provided in the substrate 50 and between the substrate 50 and the contact C5, and tapered in the Z1 direction. Thus, the insulating member INS1 having a structure for electrical insulation between the substrate 50 and the contact C5 can be formed together with the insulating member STI1. It is therefore possible to suppress an increase in the manufacturing load of the structure for electrical connection between the memory chip 100 and the circuit chip 300.

The insulating member INS2 is provided in the substrate 50 and between the substrate 50 and the contact C5 closer to the substrate 70 than the insulating member INS1, is brought into contact with the insulating member INS1, and is tapered in the Z2 direction. Thus, the insulating member INS2 can be formed after the circuit chip 200 is bonded to the memory chip 100. It is therefore possible to insulate the substrate 50 and the contact C5 electrically from each other even if the substrate 50 is thicker than the insulating member INS1.

### 1.4 Modifications to First Embodiment

Various modifications can be applied to the first embodiment. Hereinafter, a configuration and a manufacturing method different from those of the first embodiment will be mainly described. Descriptions of a configuration and a manufacturing method equivalent to those of the first embodiment will be omitted as appropriate.

### 1.4.1 First Modification to First Embodiment

In the first embodiment, the insulating member INS1 having a shape whose diameter tapers in the Z1 direction and the insulating member INS2 having a shape whose diameter tapers in the Z2 direction are provided on the substrate 50. The invention is not limited to this configuration.

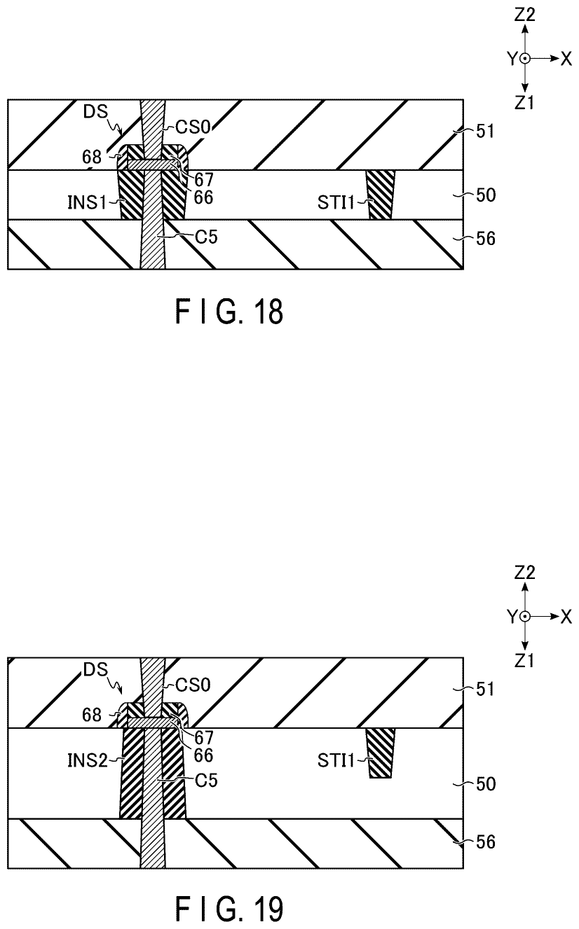

FIG. 18 is a cross-sectional view showing an example of a cross-sectional structure of a memory device according to a first modification to the first embodiment. FIG. 18 corresponds to an enlarged view of part of the member DS in FIG. 8 of the first embodiment.

As shown in FIG. 18, the substrate 50 may be thinned to have a thickness (e.g., about 400 nm through 500 nm) which is equal to that of each of the insulating members STI1 and INS1. In other words, the lower surface of each of the insulating members STI1 and INS1 in the Z2 direction may be flush with that of the substrate 50 in the Z2direction and may be in contact with the insulator layer 56. In this case, the substrate 50 is not provided with the insulating member INS2. The contact C5 extends in the Z1 direction from the lower surface of the conductive film 66 in the Z2 direction through the insulating member INS1, and reaches the conductor layer 57.

According to the first modification of the first embodiment, the thickness of the insulating member INS1 is substantially equal to that of the substrate 50. Thus, the portion of the substrate 50 connecting the transistors formed on the substrate 50 can be removed by the insulating member STI1 formed together with the insulating member INS1. It is therefore possible to suppress an unintended current leakage caused between transistors formed on the substrate 50.

In the first modification, the structure alongside the memory chip 100 and the structure alongside the circuit chip 300 with respect to the substrate 50 can be connected by the insulating member INS1 (through the substrate 50 thickness). Therefore, the step of forming the insulating member INS2 can be omitted in forming the contact C5.

### 1.4.2 Second Modification to First Embodiment

In the first embodiment, the conductive film 66 is formed to overlap a region where the insulating member INS1 is provided when viewed in the Z direction. The invention is not limited to this formation.

FIG. 19 is a cross-sectional view showing an example of the cross-sectional structure of a memory device according to a second modification to the first embodiment. FIG. 19 corresponds to an enlarged view of part of the member DS in FIG. 8 of the first embodiment.

As shown in FIG. 19, the conductive film 66 may not be provided on the insulating member INS1. In this case, in the step corresponding to FIG. 14 in the first embodiment, a groove is formed through the substrate 50. Thus, the conductive film 66 is exposed on the bottom surface of the groove in the Z1 direction. The insulator layer 56 is formed to fill the groove and thus the insulating member INS2 is formed. Therefore, the upper surface of the insulating member INS2 in the Z2 direction is flush with the lower surface of the conductive film 66 in the Z2 direction. The insulating member INS2 is thicker than the insulating member STI1. The contact C5 extends in the Z1 direction from the lower surface of the conductive film 66 in the Z2 direction through the insulating member INS2, and reaches the conductor layer 57.

According to the second modification, the insulating member INS2 is provided in the substrate 50 and between the substrate 50 and the contact C5, is brought into contact with the conductive film 66, and is tapered in the Z2direction. It is thus possible to form a region for forming the contact C5 even though the conductive film 66 is formed on the substrate 50, not on the insulating member INS1.

### 1.4.3 Third Modification to First Embodiment

In the first embodiment, a pair of insulating members INS1 and INS2 is provided for one contact C5. The invention is not limited to this configuration.

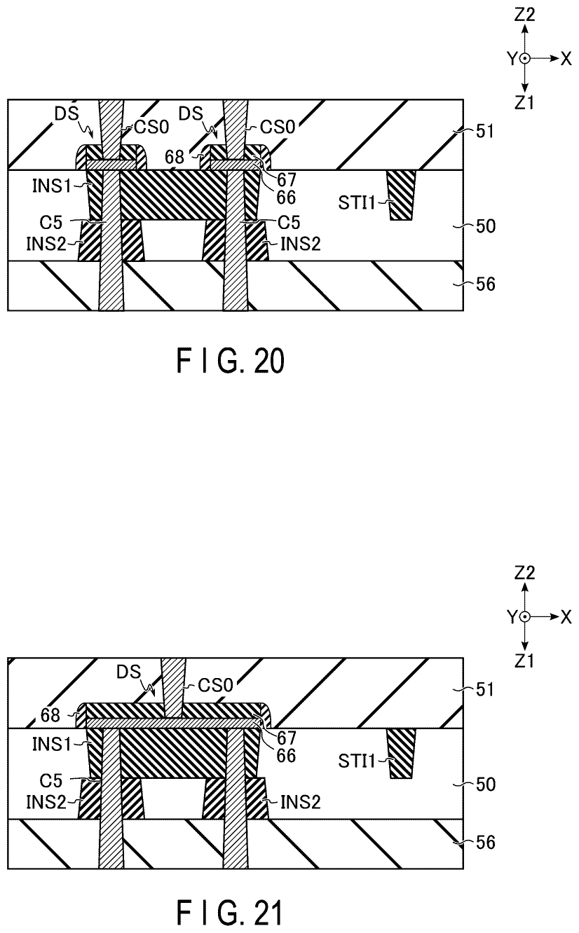

FIG. 20 is a cross-sectional view showing an example of a cross-sectional structure of a memory device according to a third modification to the first embodiment. FIG. 20 corresponds to an enlarged view of part of the member DS in FIG. 8 of the first embodiment.

As shown in FIG. 20, a common insulating member INS1 may be provided for a plurality of contacts C5. In this case, the contacts C5 are formed through the common insulating member INS1.

In addition to the example shown in FIG. 20, a common insulating member INS2 may be provided for the contacts C5. In this case, the contacts C5 are formed through the common insulating member INS2.

According to the third modification, the insulating member INS1 is provided in the substrate 50 and between the substrate 50 and the contacts C5 in the substrate 50. The insulating member INS2 may be provided in the substrate 50 and between the substrate 50 and the contacts C5. Thus, the degree of freedom in the arrangement of the contacts C5 can be improved.

### 1.4.4 Fourth Modification to First Embodiment

In the first embodiment, one contact C5 is provided for one conductive film 66. The invention is not limited to this configuration.

FIG. 21 is a cross-sectional view showing an example of a cross-sectional structure of a memory device according to a fourth modification to the first embodiment. FIG. 21 corresponds to an enlarged view of part of the member DS in FIG. 8 of the first embodiment.

As shown in FIG. 21, a plurality of contacts C5 may be provided for one conductive film 66. In this case, the contacts C5 are formed in contact with the lower surface of the conductive film 66 in the Z2 direction.

In addition to the example shown in FIG. 21, a plurality of conductive films 66 may be provided for one contact C5. In this case, the contact C5 is formed in contact with the lower surface of each of the conductive films 66 in the Z2 direction.

According to the fourth modification, the conductive film 66 is in contact with the contacts C5. The contact C5 may be in contact with a plurality of conductive films 66. Thus, the degree of freedom in the arrangement of the contacts C5 can be improved.

### 2. SECOND EMBODIMENT

Next is a description of a memory device according to a second embodiment. The second embodiment differs from the first embodiment in that a contact CS0 reaches a position in the substrate 50. Hereinafter, a configuration and a manufacturing method different from those of the first embodiment will be mainly described. Descriptions of a configuration and a manufacturing method equivalent to those of the first embodiment will be omitted as appropriate.

### 2.1 Configuration

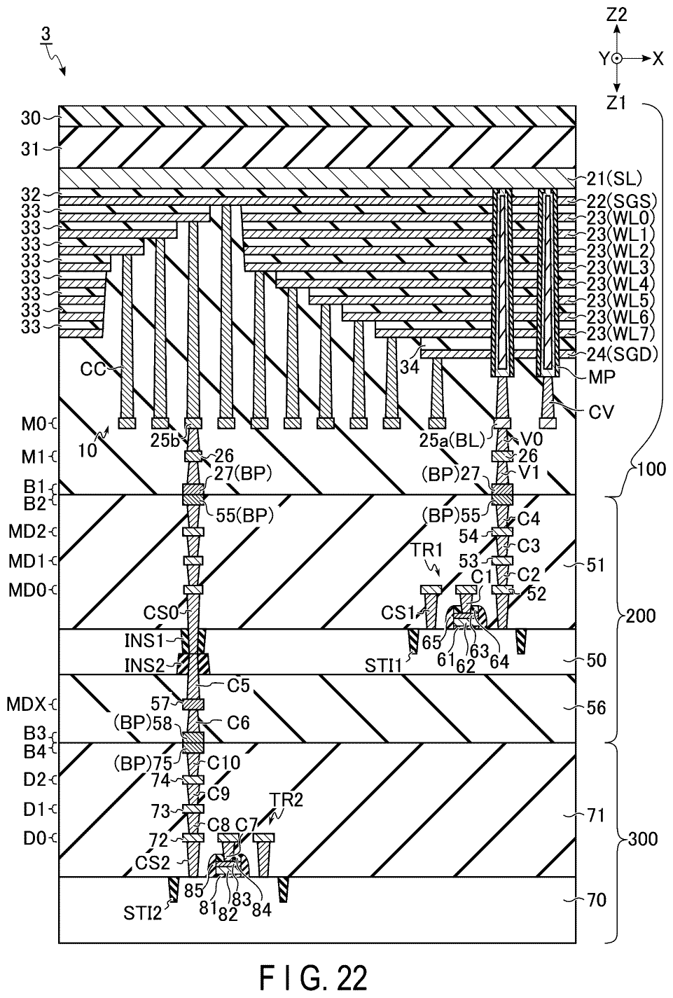

FIG. 22 is a cross-sectional view showing an example of a cross-sectional structure of the memory device according to the second embodiment. FIG. 22 corresponds to FIG. 8 of the first embodiment.

As shown in FIG. 22, in the memory device 3 of the second embodiment, no member DS is provided on the upper surface of the insulating member INS1 in the Z2 direction. In this case, the contact CS0 penetrates the insulating member INS1 and has a shape whose diameter tapers in the Z1 direction. The lower surface of the contact CS0 in the Z2 direction is flush with, for example, the lower surface of the insulating member INS1 in the Z2 direction.

A contact C5 is provided on the lower surface of the contact CS0 in the Z2 direction. The contact C5 extends in the Z1 direction through the insulating member INS2, and has a shape whose diameter tapers in the Z2 direction. The lower surface of the contact C5 in the Z2 direction reaches a position within the insulator layer 56. A conductor layer 57 is provided on the lower surface of the contact C5 in the Z2 direction. The contact C5 and the conductor layer 57 each contain, for example, copper or tungsten.

### 2.2 Manufacturing Method

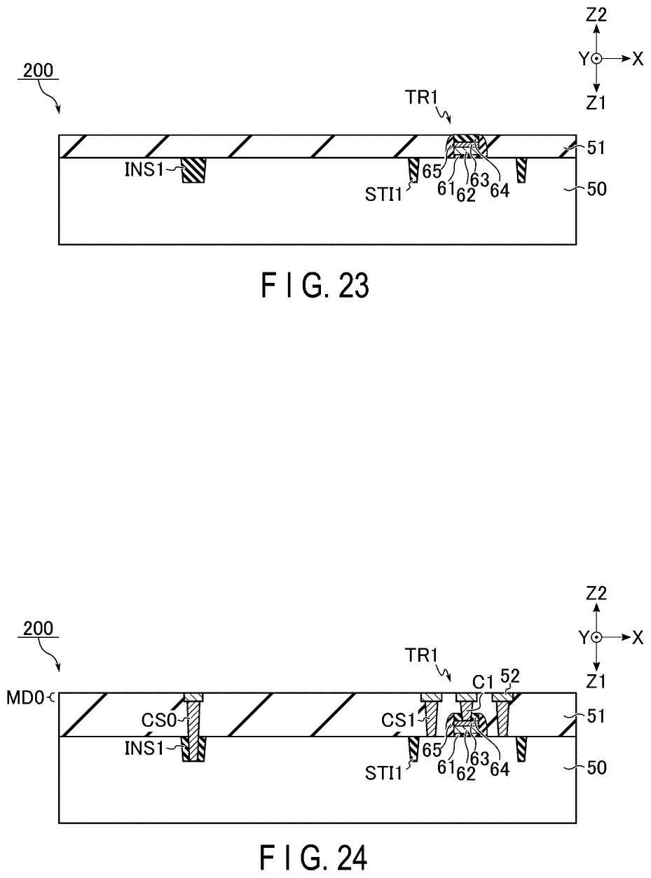

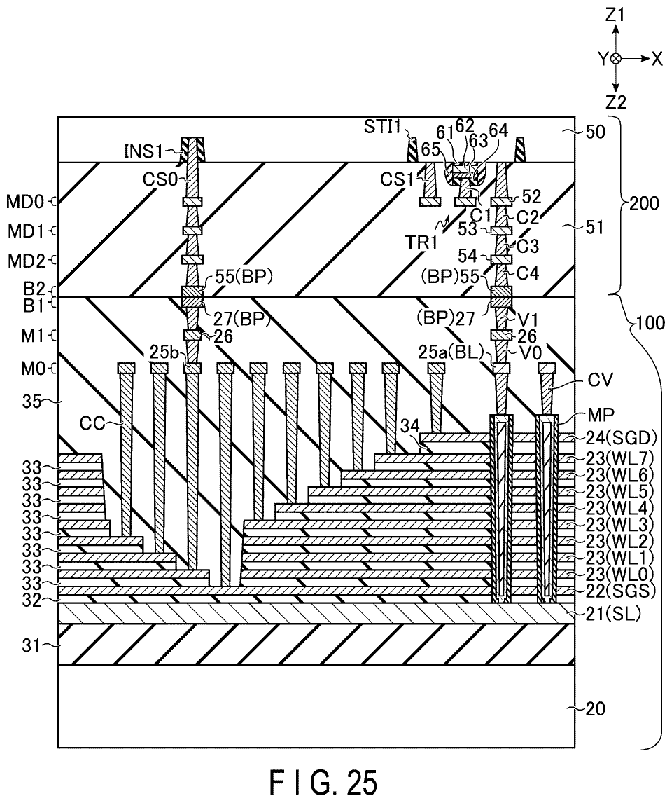

FIGS. 23 to 28 are cross-sectional views each showing an example of the cross-sectional structure in the process of manufacturing the memory device according to the second embodiment. FIGS. 23 and 24 respectively correspond to FIGS. 11 and 12 of the first embodiment. FIGS. 25 to 28 respectively correspond to FIGS. 13 to 16 of the second embodiment.

Focusing on the circuit chip 200, first, insulating members STI1 and INS1 are formed on the substrate 50 by a step similar to that in the first embodiment.

Next, as shown in FIG. 23, a transistor TR1 is formed on the upper surface of the substrate 50 in the Z2 direction. No member DS is formed on the upper surface of the insulating member INS1 in the Z2 direction. Thus, the upper surface of the insulating member INS1 in the Z2 direction is covered with the insulator layer 51.

Next, as shown in FIG. 24, a structure corresponding to the contacts C1, CS0 and CS1 and the layer MD0 is formed. The contact CS0 is positioned to overlap the insulating member INS1 when viewed in the Z direction. Thus, the contact CS0 penetrates the insulating member INS1 and reaches the substrate 50. Then, a structure corresponding to the layers MD1 and MD2 and the bonding layer B2 is formed.

Next, as shown in FIG. 25, the bonding layer B1 of the memory chip 100 and the bonding layer B2 of the circuit chip 200 are bonded together. After that, the substrate 50 of the circuit chip 200 is polished to a thickness of, for example, 500 nm or more and 2000 nm or less.

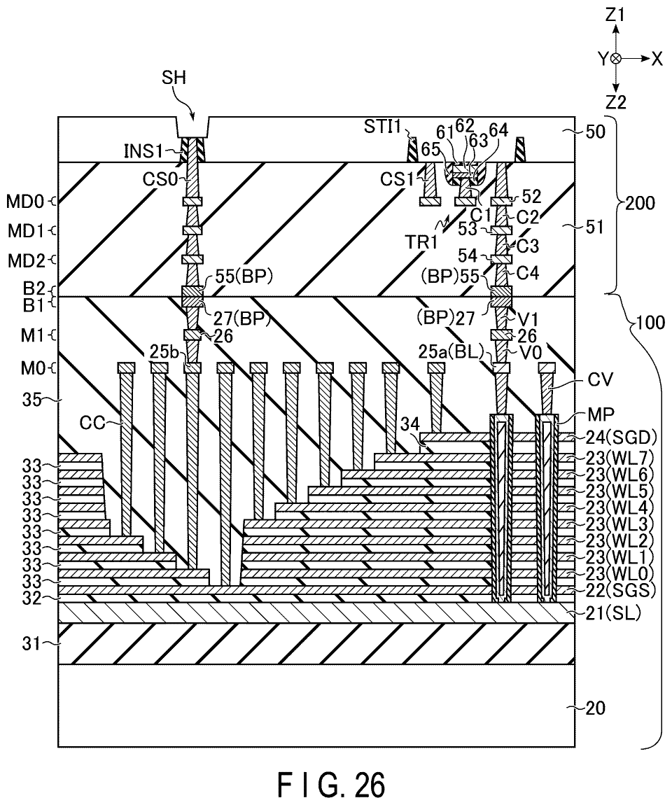

Next, as shown in FIG. 26, for example, by anisotropic etching, a groove SH is formed in a region on the upper surface of the substrate 50 in the Z1 direction where the insulating member INS2 is to be formed. Thus, the insulating member INS1 and the contact CS0 are exposed to the lower surface of the groove SH in the Z1 direction.

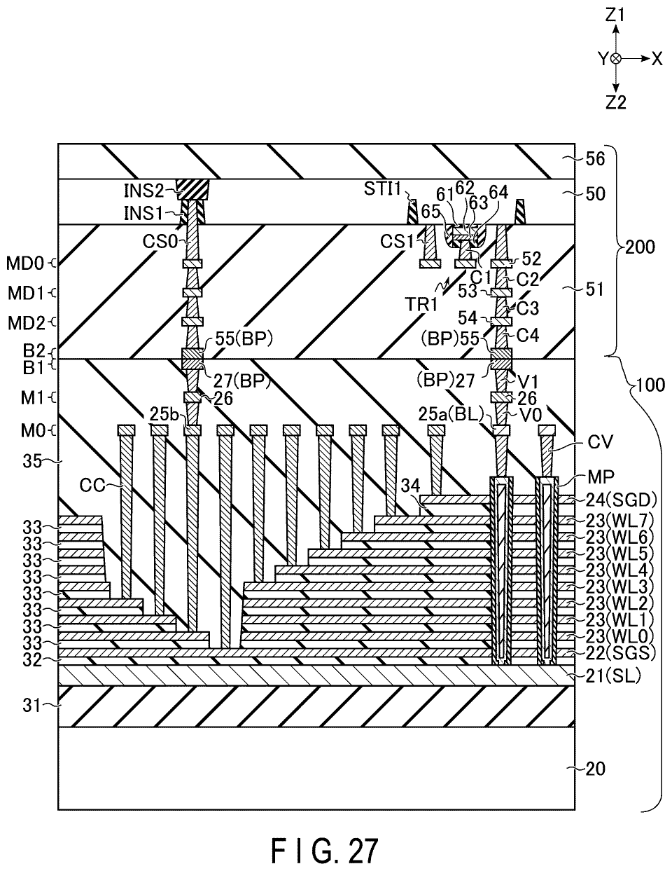

Next, as shown in FIG. 27, the insulator layer 56 is formed on the upper surface of the substrate 50 in the Z1 direction to fill the groove SH and thus form the insulating member INS2.

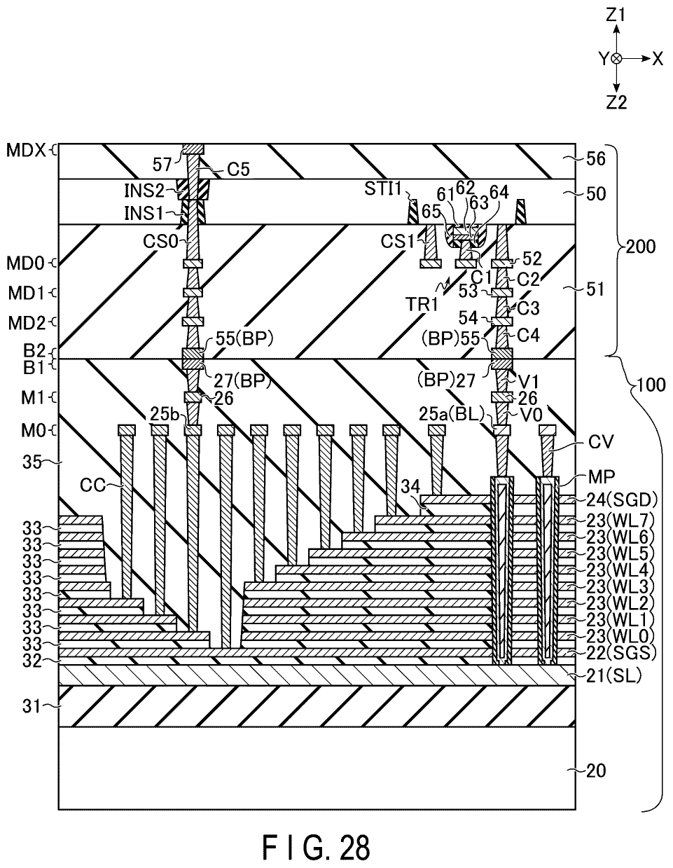

Next, as shown in FIG. 28, for example, by anisotropic etching, a contact C5 and a layer MDX are formed. Specifically, a hole is formed in a region on the upper surface of the insulator layer 56 in the Z1 direction where the contact C5 is to be formed. The hole penetrates the insulating member INS2 and reaches the contact CS0. The hole is filled, for example, with a sacrificial member. Then, a region on the upper surface of the sacrificial member in the Z1 direction where a conductor layer 57 is to be formed is opened. The opening is formed to overlap the hole filled with the sacrificial member when viewed in the Z direction and has a diameter that is larger than that of the hole. Subsequently, the sacrificial member is removed and then the contact C5 and conductor layer 57 are formed to fill the hole and opening. The contact C5 and conductor layer 57 may contain tungsten or copper.

After that, a structure corresponding to the bonding layer B3 of the circuit chip 200 is formed and then the bonding layer B3 of the circuit chip 200 and the bonding layer B4 of the circuit chip 300 are bonded together. After the substrate 20 of the memory chip 100 is removed, a power supply pad, a protective layer 30, and the like are formed. The memory device 3 is therefore formed.

### 2.3 Advantageous Effects of Second Embodiment

According to the second embodiment, the contact CS0 extends in the Z2 direction to intersect with the substrate 50. The insulating member INS1 is provided in the substrate 50 and between the substrate 50 and the contact CS0 and tapered in the Z1 direction. Thus, in forming the contact CS0 and the contact CS1 together, the contact CS0 can be formed up to the lower surface of the insulating member INS1 in the Z2 direction.

After the circuit chip 200 is adhered to the memory chip 100, the contact C5 is formed in contact with the contact CS0 that reaches the lower surface of the insulating member INS1 in the Z2 direction. Thus, the contact C5 is in contact with the contact CS0 on an end face of the insulating member INS1 alongside the substrate 70 and is tapered in the Z2 direction that is opposite to the Z1 direction in which the contact CS0 is tapered. Thus, the etching depth in the step of forming the insulating member INS2 and the filling depth in the step of forming the contact C5 can be reduced by the thickness of the insulating member INS1. Therefore, the manufacturing load of the insulating member INS2 and the contact C5 can be decreased to improve the yield of the memory device 3.

### 2.4 Modifications to Second Embodiment

In the second embodiment, various variations can be applied. Hereinafter, a configuration and a manufacturing method different from those of the second embodiment will be mainly described. Descriptions of a configuration and a manufacturing method equivalent to those of the second embodiment will be omitted as appropriate.

### 2.4.1 First Modification to Second Embodiment

In the second embodiment, the insulating member INS1 having a shape whose diameter tapers in the Z1 direction and the insulating member INS2 having a shape whose diameter tapers in the Z2 direction are provided in the substrate 50.

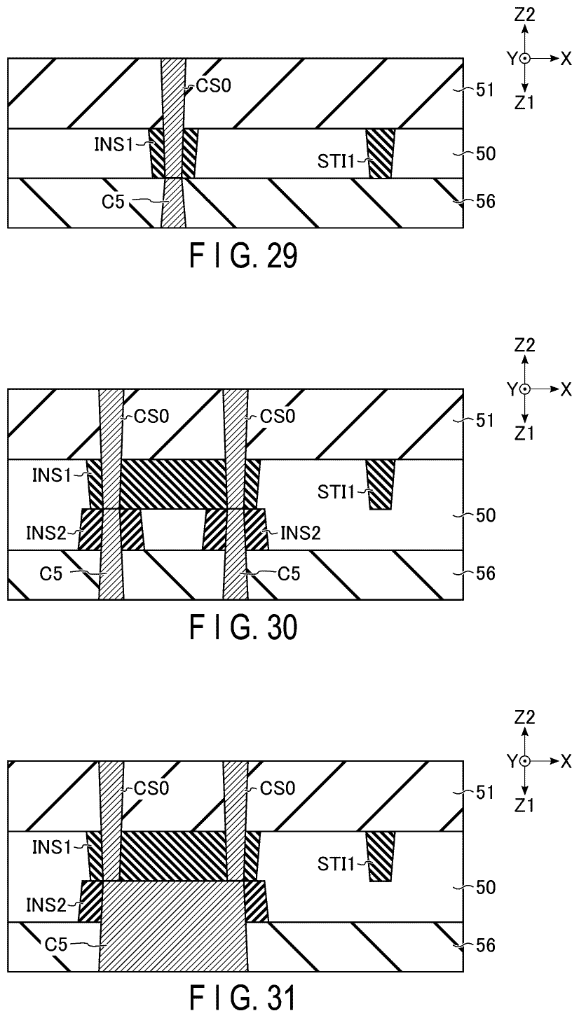

FIG. 29 is a cross-sectional view showing an example of a cross-sectional structure of a memory device according to a first modification according to the second embodiment. FIG. 29 corresponds to an enlarged view of part of the contacts CS0 and C5 in FIG. 22 according to the second embodiment.

As shown in FIG. 29, the substrate 50 may be thinned to have a film thickness (e.g., 400 nm or more and 500 nm or less) which is equal to that of each of the insulating members STI1 and INS1. In other words, the lower surface of each of the insulating members STI1 and INS1 in the Z2 direction may be flush with the lower surface of the substrate 50 in the Z2 direction and may be brought into contact with the insulator layer 56 and, in this case, the insulating member INS2 is not provided in the substrate 50. The contact C5 extends in the Z1 direction from the lower surface of the contact CS0 in the Z2 direction and reaches the conductor layer 57.

According to the first modification to the second embodiment, the thickness of the insulating member INS1 is substantially equal to that of the substrate 50. Thus, a portion of the substrate 50 which connects the transistors formed on the substrate 50 can be removed by the insulating member STI1 formed together with the insulating member INS1. It is therefore possible to suppress an unintended current leakage occurring between the transistors formed on the substrate 50.

In the first modification to the second embodiment, the structure alongside the memory chip 100 and the structure alongside the circuit chip 300 with respect to the substrate 50 can be connected by the insulating member INS1 (through the substrate 50 thickness). Therefore, the step of forming the insulating member INS2 can be omitted in forming the contact C5.

### 2.4.2 Second Modification to Second Embodiment

In the second embodiment, a pair of insulating members INS1 and INS2 is provided for one contact CS0, but the invention is not limited to this configuration.

FIG. 30 is a cross-sectional view showing an example of a cross-sectional structure of a memory device according to a second modification to the second embodiment. FIG. 30 corresponds to an enlarged view of part of the contacts CS0 and C5 in FIG. 22 of the second embodiment.

As shown in FIG. 30, a common insulating member INS1 may be provided for a plurality of contacts CS0. In this case, the contacts CS0 are provided through the common insulating member INS1.

In addition to the example shown in FIG. 30, a common insulating member INS2 may be provided for the contacts CS0 and, in this case, a number of contacts C5 which is the same as the number of contacts CS0 are provided through the common insulating member INS2.

According to the second modification to the second embodiment, the insulating member INS1 is provided in the substrate 50 and between the substrate 50 and the contacts CS0. The insulating member INS2 may be provided in the substrate 50 and between the substrate 50 and the contacts C5. Thus, the degree of freedom in the arrangement of the contacts CS0 and C5 can be improved.

### 2.4.3 Third modification to Second Embodiment

In the second embodiment, one contact C5 is provided for one contact CS0, but the invention is not limited to this configuration.

FIG. 31 is a cross-sectional view showing an example of a cross-sectional structure of a memory device according to a third modification to the second embodiment. FIG. 31 corresponds to an enlarged view of part of the contacts CS0 and C5 in FIG. 22 of the second embodiment.

As shown in FIG. 31, one contact C5 may be provided for a plurality of contacts CS0 and, in this case, the contacts CS0 are provided in contact with the upper surface of the contact C5 in the Z2 direction.

In addition to the example shown in FIG. 31, a plurality of contacts C5 may be provided for one contact CS0 and, in this case, one contact CS0 is provided in contact with the upper surface of each of the contacts C5 in the Z2 direction.

According to the third modification to the second embodiment, the contact C5 is in contact with a plurality of contacts CS0. In addition, the contact CS0 may be in contact with a plurality of contacts C5. Thus, the degree of freedom in the arrangement of the contacts CS0 and C5 can be improved.

### 3. OTHERS

In the first and second embodiments described above, the contacts CS0 and C5 electrically connect the word line WL of the memory chip 100 and the transistor TR2 of the circuit chip 300, but the invention is not limited to this configuration. The contacts CS0 and C5 may connect between any configurations of the memory chip 100 and circuit chip 300.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A memory device comprising:
a first substrate, a second substrate, and a plurality of wiring layers arranged apart from each other in this order in a first direction, the wiring layers being arranged apart from each other in the first direction;
a memory pillar extending in the first direction and having portions intersecting with respective wiring layers to function as memory cells;
a conductive film provided on a surface of the second substrate alongside the wiring layers;
a first contact extending in the first direction at a side of the wiring layers relative to the conductive film and being in contact with the conductive film; and
a second contact extending in the first direction to intersect with the second substrate at a side of the first substrate relative to the conductive film, and being in contact with the conductive film.

2. The memory device of claim 1, further comprising a first insulating member provided in the second substrate and between the second substrate and the second contact.

3. The memory device of claim 2, further comprising a second insulating member provided in the second substrate and between the second substrate and the second contact at a side of the first substrate relative to the first insulating member, being in contact with the first insulating member, and tapering in the first direction,
wherein the first insulating member tapers in a second direction opposite to the first direction.

4. The memory device of claim 2, wherein the first insulating member has a thickness that is substantially equal to a thickness of the second substrate.

5. The memory device of claim 2, further comprising a third contact extending in the first direction to intersect with the second substrate and provided apart from the second contact,
wherein the first insulating member is further provided in the second substrate and between the second substrate and the third contact.

6. The memory device of claim 2, further comprising a third contact extending in the first direction to intersect with the second substrate at the side of the first substrate relative to the conductive film, and provided apart from the second contact,
wherein the conductive film is in further contact with the third contact.

7. The memory device of claim 1, further comprising a second insulating member provided in the second substrate and between the second substrate and the second contact, being in contact with the conductive film, and tapering in the first direction.

8. The memory device of claim 1, wherein:
the first contact electrically couples between one of the memory cells and the conductive film; and
the second contact electrically couples between the first substrate and the conductive film.

9. The memory device of claim 1, further comprising a transistor provided on the surface of the second substrate alongside the wiring layers,
wherein a distance along the first direction between the surface of the second substrate alongside the wiring layers and a surface of the conductive film alongside the wiring layers is equal to or shorter than a distance along the first direction between the surface of the second substrate alongside the wiring layers and a surface of a gate electrode forming the transistor alongside the wiring layers.

10. A memory device comprising:
a first substrate, a second substrate, and a plurality of wiring layers arranged apart from each other in this order in a first direction, the wiring layers being arranged apart from each other in the first direction;
a memory pillar extending in the first direction and having portions intersecting with respective wiring layers to function as memory cells;
a first contact extending in the first direction to intersect with the second substrate; and
a first insulating member provided in the second substrate and between the second substrate and the first contact, and tapering in a second direction opposite to the first direction.

11. The memory device of claim 10, wherein the first contact tapers in the second direction.

12. The memory device of claim 11, wherein the first contact has an end face alongside the first substrate, the end face being flush with an end face of the first insulating member alongside the first substrate.

13. The memory device of claim 10, further comprising a second contact extending in the first direction, being in contact with an end face of the first contact alongside the first substrate, and tapering in the first direction.

14. The memory device of claim 13, further comprising a second insulating member provided in the second substrate and between the second substrate and the second contact, and tapering in the first direction.

15. The memory device of claim 10, wherein the first insulating member has a thickness that is substantially equal to a thickness of the second substrate.

16. The memory device of claim 10, further comprising a third contact extending in the first direction to intersect with the second substrate and provided apart from the first contact,
wherein the first insulating member is further provided in the second substrate and between the second substrate and the third contact.

17. The memory device of claim 13, further comprising a third contact extending in the first direction to intersect with the second substrate and provided apart from the first contact,
wherein the second contact is in further contact with an end face of the third contact alongside the first substrate.

18. A memory device comprising:
a first substrate, a second substrate, and a plurality of wiring layers arranged apart from each other in this order in a first direction, the wiring layers being arranged apart from each other in the first direction;
a memory pillar extending in the first direction and having portions intersecting with respective wiring layers to function as memory cells;
a first contact extending in the first direction to intersect with the second substrate and tapering in a second direction opposite to the first direction; and
a second contact extending in the first direction to intersect with the second substrate, being in contact with an end face of the first contact alongside the first substrate, and tapering in the first direction.

19. The memory device of claim 18, further comprising a first insulating member provided in the second substrate and between the second substrate and the first contact, and having an end face alongside the first substrate, the end face of the first insulating member being flush with the end face of the first contact.

20. The memory device of claim 19, wherein the first insulating member tapers in the second direction.
